(19) United States
(12) Patent Application Publication
(10) Pub. No.: US 2019/0187256 A1
(43) Pub. Date: Jun. 20, 2019

(54) NON-SPAD PIXELS FOR DIRECT TIME-OF-FLIGHT RANGE MEASUREMENT

(71) Applicant: Samsung Electronics Co., Ltd., Suwon-si (KR)

(72) Inventor: Yibing Michelle WANG, Pasadena, CA (US)

(21) Appl. No.: 15/920,430

(22) Filed: Mar. 13, 2018

Related U.S. Application Data
(60) Provisional application No. 62/607,861, filed on Dec. 19, 2017.

(51) Int. Cl. G01S 7/486; G01S 17/10; G01S 17/93; G01S 17/89

(52) U.S. Cl. CPC G01S 7/4863; G01S 17/10; H01L 27/14645; G01S 17/89; G01S 17/936

(57) ABSTRACT

A Direct Time-of-Flight (DTOF) technique is combined with analog amplitude modulation within each pixel in a pixel array. No Single Photon Avalanche Diodes (SPADs) or Avalanche Photo Diodes (APDs) are used. Instead, each pixel has a Photo Diode (PD) with a conversion gain of over 400 μV/e− and Photon Detection Efficiency (PDE) of more than 45%, operating in conjunction with a Pinned Photo Diode (PPD). The TOF information is added to the received light signal by the analog domain-based single-ended to differential converter inside the pixel itself. The output of the PD in a pixel is used to control the operation of the PPD. The charge transfer from the PPD is stopped—and, hence, TOF value and range of an object are recorded—when the output from the PD in the pixel is triggered within a pre-defined time interval. Such pixels provide for an improved autonomous navigation system for drivers.

### CROSS-REFERENCE TO RELATED APPLICATION

This application claims the priority benefit under 35 U.S.C. § 119(e) of U.S. Provisional Application No. 62/607,861 filed on Dec. 19, 2017, the disclosure of which is incorporated herein by reference in its entirety.

### TECHNICAL FIELD

The present disclosure generally relates to image sensors. More specifically, and not by way of limitation, particular embodiments of the inventive aspects disclosed in the present disclosure are directed to a Time-of-Flight (TOF) image sensor in which a pixel uses a Photo Diode (PD) with a very high conversion gain to control the operation of a time-to-charge converter, such as a Pinned Photo Diode (PPD), to facilitate recording of TOF values and range of a three-dimensional (3D) object.

### BACKGROUND

Three-dimensional (3D) imaging systems are increasingly being used in a wide variety of applications such as, for example, industrial production, video games, computer graphics, robotic surgeries, consumer displays, surveillance videos, 3D modeling, real estate sales, autonomous navigation, and so on.

Existing 3D imaging technologies may include, for example, the time-of-flight (TOF) based range imaging, stereo vision systems, and structured light (SL) methods.

In the TOF method, distance to a 3D object is resolved based on the known speed of light—by measuring the round-trip time it takes for a light signal to travel between a camera and the 3D object for each point of the image. The outputs of pixels in the camera provide information about pixel-specific TOF values to generate a 3D depth profile of the object. A TOF camera may use a scanner-less approach to capture the entire scene with each laser or light pulse. In a direct TOF imager, a single laser pulse may be used to capture spatial and temporal data to record a 3D scene. This allows rapid acquisition and rapid real-time processing of scene information. Some example applications of the TOF method may include advanced automotive applications such as autonomous navigation and active pedestrian safety or pre-crash detection based on distance images in real time, to track movements of humans such as during interaction with games on video game consoles, in industrial machine vision to classify objects and help robots find the items such as items on a conveyor belt, and so on.

Light Detection and Ranging (LiDAR) is an example of a direct TOF method that measures distance to a target by illuminating the target with a pulsed laser light and measuring the reflected pulses with a sensor. Differences in laser return times and wavelengths can then be used to make digital 3D representations of the target. LiDAR has terrestrial, airborne, and mobile applications. LiDAR is commonly used to make high-resolution maps such as, for example, in archaeology, geography, geology, forestry, and the like. LiDAR also has automotive applications such as, for example, for control and navigation in some autonomous cars.

In stereoscopic imaging or stereo vision systems, two cameras—displaced horizontally from one another—are used to obtain two differing views on a scene or a 3D object in the scene. By comparing these two images, the relative depth information can be obtained for the 3D object. Stereo vision is highly important in fields such as robotics, to extract information about the relative position of 3D objects in the vicinity of autonomous systems/robots. Other applications for robotics include object recognition, where stereoscopic depth information allows a robotic system to separate occluding image components, which the robot may otherwise not be able to distinguish as two separate objects—such as one object in front of another, partially or fully hiding the other object. 3D stereo displays are also used in entertainment and automated systems.

In the SL approach, the 3D shape of an object may be measured using projected light patterns and a camera for imaging. In the SL method, a known pattern of light—often grids or horizontal bars or patterns of parallel stripes—is projected onto a scene or a 3D object in the scene. The projected pattern may get deformed or displaced when striking the surface of the 3D objet. Such deformation may allow an SL vision system to calculate the depth and surface information of the object. Thus, projecting a narrow band of light onto a 3D surface may produce a line of illumination that may appear distorted from other perspectives than that of the projector, and can be used for geometric reconstruction of the illuminated surface shape. The SL-based 3D imaging may be used in different applications such as, for example, by a police force to photograph fingerprints in a 3D scene, inline inspection of components during a production process, in health care for live measurements of human body shapes or the micro structures of human skin, and the like.

### SUMMARY

In one embodiment, the present disclosure is directed to a pixel in an image sensor. The pixel comprises: (i) a Photo Diode (PD) unit having at least one PD that converts received luminance into an electrical signal, wherein the at least one PD has a conversion gain that satisfies a threshold; (ii) an amplifier unit connected in series with the PD unit to amplify the electrical signal and to responsively generate an intermediate output; and (iii) a Time-to-Charge Converter (TCC) unit coupled to the amplifier unit and receiving the intermediate output therefrom. In the pixel, the TCC unit includes: (a) a device that stores an analog charge, and (b) a control circuit coupled to the device. The control circuit performs operations comprising: (1) initiating transfer of a portion of the analog charge from the device, (2) terminating the transfer in response to receipt of the intermediate output within a pre-defined time interval, and (3) generating a pixel-specific output for the pixel based on the portion of the analog charge transferred. In particular embodiments, the threshold for the conversion gain is at least 400 μV (microvolts) per photoelectron.

In another embodiment, the present disclosure is directed to a method, which comprises: (i) projecting a laser pulse onto a three-dimensional (3D) object; (ii) applying an analog modulating signal to a device in a pixel, wherein the device stores an analog charge; (iii) initiating transfer of a portion of the analog charge from the device based on modulation received from the analog modulating signal; (iv) detecting a returned pulse using the pixel, wherein the returned pulse is the projected laser pulse reflected from the 3D object, and wherein the pixel includes a Photo Diode (PD) unit having at least one PD that converts luminance received in the returned pulse into an electrical signal and that has a conversion gain that satisfies a threshold; (v) processing the electrical signal using an amplifier unit in the pixel to responsively generate an intermediate output; (vi) terminating the transfer of the portion of the analog charge in response to generation of the intermediate output within a pre-defined time interval; and (vii) determining a Time of Flight (TOF) value of the returned pulse based on the portion of the analog charge transferred upon termination. In some embodiments, the threshold for the conversion gain is at least 400 μV per photon.

In yet another embodiment, the present disclosure is directed to a system, which comprises: (i) a light source; (ii) a plurality of pixels; (iii) a memory for storing program instructions; and (iv) a processor coupled to the memory and to the plurality of pixels. In the system, the light source projects a laser pulse onto a 3D object. In the plurality of pixels, each pixel includes: (a) a pixel-specific PD unit having at least one PD that converts luminance received in a returned pulse into an electrical signal, wherein the at least one PD has a conversion gain that satisfies a threshold, and wherein the returned pulse results from reflection of the projected laser pulse by the 3D object; (b) a pixel-specific amplifier unit connected in series with the pixel-specific PD unit to amplify the electrical signal and to responsively generate an intermediate output; and (c) a pixel-specific TCC unit coupled to the pixel-specific amplifier unit and receiving the intermediate output therefrom. In the system, the pixel-specific TCC unit includes: (i) a device that stores an analog charge, and (ii) a control circuit coupled to the device. The control circuit performs operations comprising: (a) initiating transfer of a pixel-specific first portion of the analog charge from the device; (b) terminating the transfer of the pixel-specific first portion upon receipt of the intermediate output within a pre-defined time interval; (c) generating a first pixel-specific output for the pixel based on the pixel-specific first portion of the analog charge transferred; (d) transferring a pixel-specific second portion of the analog charge from the device, wherein the pixel-specific second portion is substantially equal to a remainder of the analog charge after the pixel-specific first portion is transferred; and (e) generating a second pixel-specific output for the pixel based on the pixel-specific second portion of the analog charge transferred. In the system, the processor executes the program instructions, whereby the processor performs the following operations for each pixel in the plurality of pixels: (a) facilitating transfers of the pixel-specific first and second portions of the analog charge, respectively; (b) receiving the first and the second pixel-specific outputs; (c) generating a pixel-specific pair of signal values based on the first and the second pixel-specific outputs, respectively, wherein the pixel-specific pair of signal values includes a pixel-specific first signal value and a pixel-specific second signal value; (d) determining a corresponding pixel-specific TOF value of the returned pulse using the pixel-specific first signal value and the pixel-specific second signal value; and (e) determining a pixel-specific distance to the 3D object based on the pixel-specific TOF value. In certain embodiments, the threshold for the conversion gain is at least 400 μV per photoelectron.

### BRIEF DESCRIPTION OF THE DRAWINGS

In the following section, the inventive aspects of the present disclosure will be described with reference to exemplary embodiments illustrated in the figures, in which:

FIG. 1 shows a highly simplified, partial layout of a LiDAR TOF imaging system according to one embodiment of the present disclosure;

FIG. 2 illustrates an exemplary operational layout of the system in FIG. 1 according to one embodiment of the present disclosure;

FIG. 3 depicts exemplary circuit details of a pixel according to certain embodiments of the present disclosure;

FIG. 4 shows exemplary circuit details of another pixel according to some embodiments of the present disclosure;

FIG. 5 provides circuit details of an exemplary TCC unit in a pixel as per particular embodiments of the present disclosure;

FIG. 6 is an exemplary timing diagram that provides an overview of the modulated charge transfer mechanism in the TCC unit of FIG. 5 according to one embodiment of the present disclosure;

FIG. 7 shows the block diagram of an exemplary logic unit that may be used in the TCC unit of FIG. 5 as per particular embodiments of the present disclosure;

FIG. 8 is a timing diagram that shows exemplary timing of different signals in the system of FIGS. 1-2 when the TCC unit in the embodiment of FIG. 5 is used in a pixel as part of a pixel array for measuring TOF values according to certain embodiments of the present disclosure;

FIG. 9 shows circuit details of another exemplary TCC unit as per particular embodiments of the present disclosure;

FIG. 10 is a timing diagram that shows exemplary timing of different signals in the system of FIGS. 1-2 when the TCC unit in the embodiment of FIG. 9 is used in a pixel as part of a pixel array for measuring TOF values according to certain embodiments of the present disclosure;

FIG. 11 depicts an exemplary flowchart showing how a TOF value may be determined in the system of FIGS. 1-2 according to one embodiment of the present disclosure; and

FIG. 12 depicts an overall layout of the system in FIGS. 1-2 according to one embodiment of the present disclosure.

### DETAILED DESCRIPTION

In the following detailed description, numerous specific details are set forth in order to provide a thorough understanding of the disclosure. However, it will be understood by those skilled in the art that the disclosed inventive aspects may be practiced without these specific details. In other instances, well-known methods, procedures, components and circuits have not been described in detail so as not to obscure the present disclosure. Additionally, the described inventive aspects can be implemented to perform low power, range measurements and 3D imaging in any imaging device or system, including, for example, a computer, an automobile navigation system, and the like.

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” or “according to one embodiment” (or other phrases having similar import) in various places throughout this specification are not necessarily all referring to the same embodiment. Furthermore, the particular features, structures, or characteristics may be combined in any suitable manner in one or more embodiments. Also, depending on the context of discussion herein, a singular term may include its plural forms and a plural term may include its singular form. Similarly, a hyphenated term (e.g., “three-dimensional,” “pre-defined”, “pixel-specific,” etc.) may be occasionally interchangeably used with its non-hyphenated version (e.g., “three dimensional,” “predefined”, “pixel specific,” etc.), and a capitalized entry (e.g., “Projector Module,” “Image Sensor,” “PIXOUT” or “Pixout,” etc.) may be interchangeably used with its non-capitalized version (e.g., “projector module,” “image sensor,” “pixout,” etc.). Such occasional interchangeable uses shall not be considered inconsistent with each other.

It is noted at the outset that the terms “coupled,” “operatively coupled,” “connected”, “connecting,” “electrically connected,” etc., may be used interchangeably herein to generally refer to the condition of being electrically/electronically connected in an operative manner. Similarly, a first entity is considered to be in “communication” with a second entity (or entities) when the first entity electrically sends and/or receives (whether through wireline or wireless means) information signals (whether containing address, data, or control information) to/from the second entity regardless of the type (analog or digital) of those signals. It is further noted that various figures (including component diagrams) shown and discussed herein are for illustrative purpose only, and are not drawn to scale. Similarly, various waveforms and timing diagrams are shown for illustrative purpose only.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. However, such usage is for simplicity of illustration and ease of discussion only; it does not imply that the construction or architectural details of such components or units are the same across all embodiments or such commonly-referenced parts/modules are the only way to implement the teachings of particular embodiments of the present disclosure.

It is observed here that the earlier-mentioned 3D technologies have many drawbacks. For example, a range gated TOF imager may use multiple laser pulses to provide illumination and an optical gate to allow the light to reach the imager only during a desired time period. The range gated TOF imagers can be used in two-dimensional (2D) imaging to suppress anything outside a specified distance range, such as to see through fog. However, the gated TOF imagers may provide only Black-and-White (B&W) output and may not have 3D imaging capability. Furthermore, current TOF systems typically operate over a range of few meters to several tens of meters, but their resolution may decrease for measurements over short distances, thereby making 3D imaging within a short distance—such as, for example, in a fog or hard-to-see conditions—almost impractical. Also, pixels in existing TOF sensors may be vulnerable to ambient light.

Direct TOF (DTOF) LiDAR sensors typically use Single Photon Avalanche Diodes (SPADs) or Avalanche Photo Diodes (APDs) in their pixel arrays for DTOF range measurements. Generally, SPAD and APD both require a high operating voltage—in the range of approximately 20V to 30V—and special fabrication processes to manufacture them. Furthermore, a SPAD has a low Photon Detection Efficiency (PDE) in the range of 5%. Thus, a SPAD based imager may not be optimum for a high speed 3D imaging system for all-weather autonomous navigation.

The stereoscopic imaging approach generally works only with textured surfaces. It has high computational complexity because of the need to match features and find correspondences between the stereo pair of images of an object. This requires high system power. Furthermore, stereo imaging requires two regular, high bit resolution sensors along with two lenses, making the entire assembly unsuitable where space is at a premium such as, for example, in an automobile-based autonomous navigation system. Additionally, stereo 3D cameras have difficulty to see through fog and to deal with motion blur.

In contrast, particular embodiments of the present disclosure provide for implementing a lost cost, high performance automotive LiDAR sensor or DTOF-based 3D imaging system on automotives for all weather conditions. Thus, improved vision for drivers may be provided under difficult conditions such as, for example, low light, bad weather, fog, strong ambient light, and the like. A DTOF range measurement system as per particular embodiments of the present disclosure may not include imaging, but, instead, may provide an audible and/or a visible alert. The measured range may be used in autonomous control of a vehicle such as, for example, automatically stopping a vehicle to avoid collision with another object. As discussed in more detail below, in a single pulse-based direct TOF system as per particular embodiments of the present disclosure, the TOF information is added to the received signal by means of controlled charge transferring and analog domain-based single-ended to differential converter inside the pixel itself. Thus, the present disclosure provides for a single chip solution that directly combines TOF and analog Amplitude Modulation (AM) within each pixel in the pixel array using a high conversion Photo Diode (PD)-having PDE in the range of 45% or more—in conjunction with a single Pinned Photo Diode (PPD) (or another time-to-charge converter) in each pixel. The high conversion PDs replace the SPADs in the current LiDAR imagers for DTOF range measurements. The output of the PD in a pixel is used to control the operation of the PPD to facilitate recording of TOF values and range of a 3D object. As a result, an improved autonomous navigation system may be offered that can “see through” inclement weather at short range and produce 3D images as well as 2D gray-scale images under a substantially lower operating voltage.

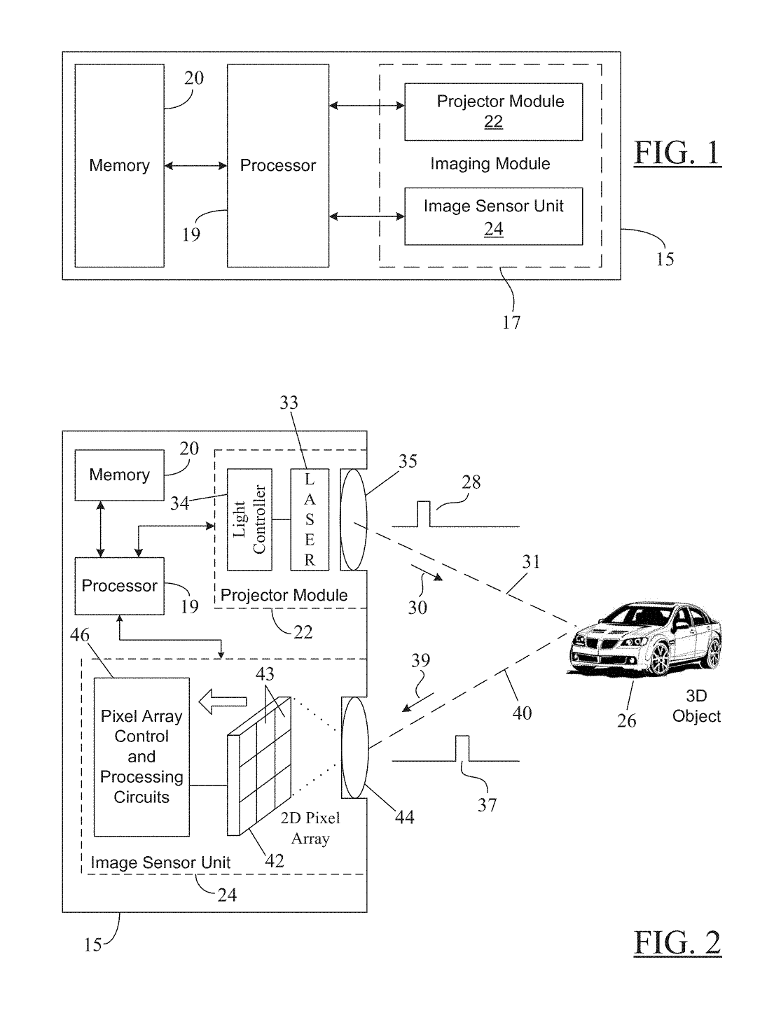

FIG. 1 shows a highly simplified, partial layout of a LiDAR TOF imaging system 15 according to one embodiment of the present disclosure. As shown, the system 15 may include an imaging module 17 coupled to and in communication with a processor or host 19. The system 15 may also include a memory module 20 coupled to the processor 19 to store information content such as, for example, image data received from the imaging module 17. In particular embodiments, the entire system 15 may be encapsulated in a single Integrated Circuit (IC) or chip. Alternatively, each of the modules 17, 19, and 20 may be implemented in a separate chip. Furthermore, the memory module 20 may include more than one memory chip, and the processor module 19 may comprise of multiple processing chips as well. In any event, the details about packaging of the modules in FIG. 1 and how they are fabricated or implemented—in a single chip or using multiple discrete chips—are not relevant to the present discussion and, hence, such details are not provided herein.

The system 15 may be any electronic device configured for 2D and 3D imaging applications as per teachings of the present disclosure. The system 15 may be portable or non-portable. Some examples of the portable version of the system 15 may include popular consumer electronic gadgets such as, for example, a mobile device, a cellphone, a smartphone, a User Equipment (UE), a tablet, a digital camera, a laptop or desktop computer, an automobile navigation unit, a Machine-to-Machine (M2M) communication unit, a Virtual Reality (VR) equipment or module, a robot, and the like. On the other hand, some examples of the non-portable version of the system 15 may include a game console in a video arcade, an interactive video terminal, an automobile with autonomous navigation capability, a machine vision system, an industrial robot, a VR equipment, and so on. The 3D imaging functionality provided as per teachings of the present disclosure may be used in many applications such as, for example, automobile applications such as all-weather autonomous navigation and driver assistance in low light or inclement weather conditions, human-machine interface and gaming applications, machine vision and robotics applications, and the like.

In particular embodiments of the present disclosure, the imaging module 17 may include a projector module (or light source module) 22 and an image sensor unit 24. As discussed in more detail with reference to FIG. 2 below, in one embodiment, the light source in the projector module 22 may be an Infrared (IR) laser such as, for example, a Near Infrared (NIR) or a Short Wave Infrared (SWIR) laser, to make the illumination unobtrusive. In other embodiments, the light source may be a visible light laser. The image sensor unit 24 may include a pixel array and ancillary processing circuits as shown in FIG. 2 and also discussed below.

In one embodiment, the processor 19 may be a Central Processing Unit (CPU), which can be a general purpose microprocessor. In the discussion herein, the terms “processor” and “CPU” may be used interchangeably for ease of discussion. However, it is understood that, instead of or in addition to the CPU, the processor 19 may contain any other type of processors such as, for example, a microcontroller, a Digital Signal Processor (DSP), a Graphics Processing Unit (GPU), a dedicated Application Specific Integrated Circuit (ASIC) processor, and the like. Furthermore, in one embodiment, the processor/host 19 may include more than one CPU, which may be operative in a distributed processing environment. The processor 19 may be configured to execute instructions and to process data according to a particular Instruction Set Architecture (ISA) such as, for example, an x86 instruction set architecture (32-bit or 64-bit versions), a PowerPC® ISA, or a MIPS (Microprocessor without Interlocked Pipeline Stages) instruction set architecture relying on RISC (Reduced Instruction Set Computer) ISA. In one embodiment, the processor 19 may be a System on Chip (SoC) having functionalities in addition to a CPU functionality.

In particular embodiments, the memory module 20 may be a Dynamic Random Access Memory (DRAM) such as, for example, a Synchronous DRAM (SDRAM), or a DRAM-based Three Dimensional Stack (3DS) memory module such as, for example, a High Bandwidth Memory (HBM) module, or a Hybrid Memory Cube (HMC) memory module. In other embodiments, the memory module 20 may be a Solid State Drive (SSD), a non-3DS DRAM module, or any other semiconductor-based storage system such as, for example, a Static Random Access Memory (SRAM), a Phase-Change Random Access Memory (PRAM or PCRAM), a Resistive Random Access Memory (RRAM or ReRAM), a Conductive-Bridging RAM (CBRAM), a Magnetic RAM (MRAM), a Spin-Transfer Torque MRAM (STT-MRAM), and the like.

FIG. 2 illustrates an exemplary operational layout of the system 15 in FIG. 1 according to one embodiment of the present disclosure. The system 15 may be used to obtain range measurements (and, consequently, a 3D image) for a 3D object, such as the 3D object 26, which may be an individual object or an object within a group of other objects. In one embodiment, the range and 3D depth information may be calculated by the processor 19 based on the measurement data received from the image sensor unit 24. In another embodiment, the range/depth information may be calculated by the image sensor unit 24 itself. In particular embodiments, the range information may be used by the processor 19 as part of a 3D user interface to enable the user of the system 15 to interact with the 3D image of the object or use the 3D image of the object as part of games or other applications—like an autonomous navigation application—running on the system 15. The 3D imaging as per teachings of the present disclosure may be used for other purposes or applications as well, and may be applied to substantially any 3D object, whether stationary or in motion.

The light source (or projector) module 22 may illuminate the 3D object 26 by projecting a short pulse 28 as shown by an exemplary arrow 30 associated with a corresponding dotted line 31 representing an illumination path of a light signal or optical radiation that may be used to project on the 3D object 26 within an optical Field Of View (FOV). The system 15 may be a direct TOF imager in which a single pulse may be used per image frame (of pixel array). In certain embodiments, multiple, short pulses may be transmitted onto the 3D object 26 as well. An optical radiation source, which, in one embodiment, may be a laser light source 33 operated and controlled by a laser controller 34, may be used to project the short pulse 28 (here, a laser pulse) onto the 3D object 26. The short pulse 28 from the laser light source 33 may be projected—under the control of the laser controller 34—onto the surface of the 3D object 26 via projection optics 35. The projection optics may be a focusing lens, a glass/plastics surface, or other cylindrical optical element. In the embodiment of FIG. 2, a convex structure, such as a focusing lens, is shown as projection optics 35. However, any other suitable lens design or an external optical cover may be selected for projection optics 35.

In particular embodiments, the light source (or illumination source) 33 may be a diode laser or a Light Emitting Diode (LED) emitting visible light, a light source that produces light in the non-visible spectrum, an IR laser (for example, an NIR or an SWIR laser), a point light source, a monochromatic illumination source (such as, for example, a combination of a white lamp and a monochromator) in the visible light spectrum, or any other type of laser light source. In autonomous navigation applications, the more unobtrusive NIR or SWIR laser may be preferred as the pulsed laser light source 33. In certain embodiments, the laser light source 33 may be one of many different types of laser light sources such as, for example, a point source with 2D scanning capability, a sheet source with one-dimensional (1D) scanning capability, or a diffused laser with matching FOV of the image sensor unit 24. In particular embodiments, the laser light source 33 may be fixed in one position within the housing of the device 15, but may be rotatable in X-Y directions. The laser light source 33 may be X-Y addressable (for example, by the laser controller 34) to perform a scan of the 3D object 26. The laser pulse 28 may be projected onto the surface of the 3D object 26 using a mirror (not shown), or the projection may be completely mirror-less. In particular embodiments, the projector module 22 may include more or less components than those shown in the exemplary embodiment of FIG. 2.

In the embodiment of FIG. 2, the light/pulse 37—also referred to as the “returned pulse”—reflected from the object 26 may travel along a collection path indicated by an arrow 39 adjacent to a dotted line 40. The light collection path may carry photons reflected from or scattered by the surface of the object 26 upon receiving illumination from the laser source 33. It is noted here that the depiction of various propagation paths using solid arrows and dotted lines in FIG. 2 is for illustrative purpose only. The depiction should not be construed to illustrate any actual optical signal propagation paths. In practice, the illumination and collection signal paths may be different from those shown in FIG. 2, and may not be as clearly-defined as in the illustration in FIG. 2.

In TOF imaging, the light received from the illuminated 3D object 26 may be focused onto a 2D pixel array 42 via collection optics 44 in the image sensor unit 24. The pixel array 42 may include one or more pixels 43. Like the projection optics 35, the collection optics 44 may be a focusing lens, a glass/plastics surface, or other cylindrical optical element that concentrates the reflected light received from the 3D object 26 onto one or more pixels 43 in the 2D array 42. An optical band-pass filter (not shown) may be used as part of the collection optics 44 to pass only the light with the same wavelength as the wavelength of light in the laser pulse 28. This may help suppress collection/reception of non-relevant light and reduce noise. In the embodiment of FIG. 2, a convex structure, such as a focusing lens, is shown as the collection optics 44. However, any other suitable lens design or optical covering may be selected for collection optics 44. Furthermore, for ease of illustration, only a 3×3 pixel array is shown in FIG. 2. However, it is understood that, modern pixel arrays contain thousands or even millions of pixels.

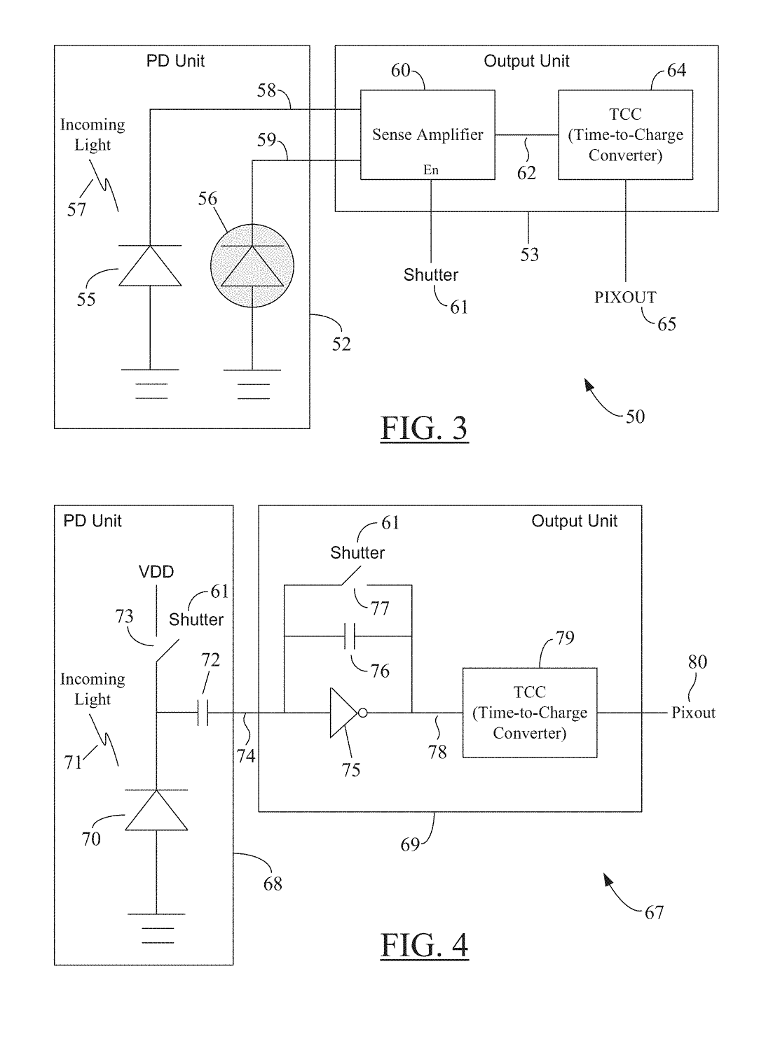

The TOF-based 3D imaging as per particular embodiments of the present disclosure may be performed using many different combinations of 2D pixel arrays 42 and laser light sources 33 such as, for example: (i) a 2D color (RGB) sensor with a visible light laser source, in which the laser source may be a red (R), green (G), or blue (B) light laser, or a laser source producing a combination of these lights; (ii) a visible light laser with a 2D RGB color sensor having an Infrared (IR) cut filter; (iii) an NIR or SWIR laser with a 2D IR sensor; (iv) an NIR laser with a 2D NIR sensor; (v) an NIR laser with a 2D RGB sensor (without an IR cut filter); (vi) an NIR laser with a 2D RGB sensor (without an NIR cut filter); (vii) a 2D RGB-IR sensor with visible or IR laser; (viii) a 2D RGBW (red, green, blue, white) or RWB (red, white, blue) sensor with either visible or NIR laser; and so on. In case of an NIR or other IR laser as, for example, in autonomous navigation applications, the 2D pixel array 42 may provide outputs to generate a grayscale image of the 3D object 26. These pixel outputs also may be processed to obtain the range measurements and, hence, to generate a 3D image of the object 26, as discussed in more detail below. Exemplary circuit details of individual pixels 43 are shown and discussed later with reference to FIGS. 3-5, 7, and 9.

The pixel array 42 may convert the received photons into corresponding electrical signals, which are then processed by the associated image processing unit 46 to determine the range and 3D depth image of the object 26. In one embodiment, the image processing unit 46 and/or the processor 19 may carry out range measurements. As noted in FIG. 2, the image processing unit 46 may also include relevant processing circuits and circuits for controlling the operation of the pixel array 42. It is noted here that both the projector module 22 and the pixel array 42 may have to be controlled by high speed signals and synchronized. These signals have to be very accurate to obtain a high resolution. Hence, the processor 19 and the image processing unit 46 may be configured to provide relevant signals with accurate timing and high precision.

In the TOF system 15 in the embodiment of FIG. 2, the image processing unit 46 may receive a pair of pixel-specific outputs from each pixel 43 to measure the pixel-specific time (pixel-specific TOF value) the light has taken to travel from the projector module 22 to the object 26 and back to the pixel array 42. The timing calculation may use the approach discussed below. Based on the calculated TOF values, in certain embodiments, the pixel-specific distance to the object 26 may be calculated by the image processing unit 46 directly in the image sensor unit 24 to enable the processor 19 to provide a 3D distance image of the object 26 over some interface—such as, for example, a display screen or user interface.

The processor 19 may control the operations of the projector module 22 and the image sensor unit 24. Upon user input or automatically (as, for example, in a real-time autonomous navigation application), the processor 19 may repeatedly send a laser pulse 28 onto the surrounding 3D object(s) 26 and trigger the sensor unit 24 to receive and process incoming returned pulses 37. The processed image data received from the image processing unit 46 may be stored by the processor 19 in the memory 20 for TOF-based range computation and 3D image generation (if applicable). The processor 19 may also display a 2D image (for example, a grayscale image) and/or a 3D image on a display screen (not shown) of the device 15. The processor 19 may be programmed in software or firmware to carry out various processing tasks described herein. Alternatively or additionally, the processor 19 may comprise programmable hardware logic circuits for carrying out some or all of its functions. In particular embodiments, the memory 20 may store program code, look-up tables, and/or interim computational results to enable the processor 19 to carry out its functions.

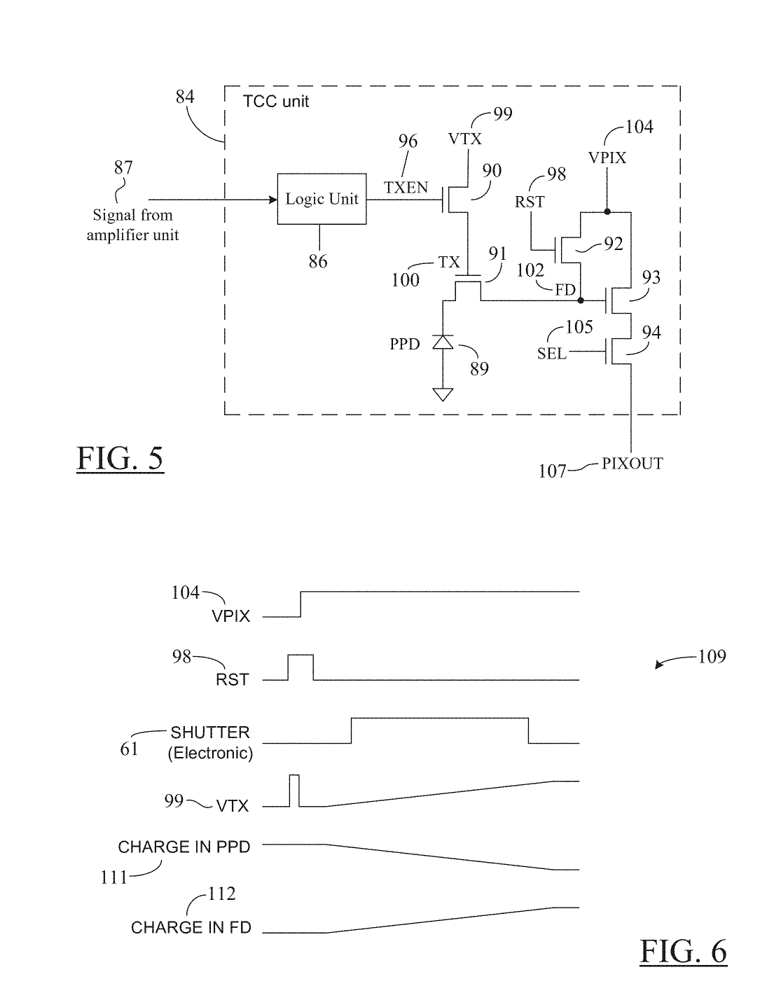

FIG. 3 depicts exemplary circuit details of a pixel 50 according to certain embodiments of the present disclosure. The pixel 50 is an example of the pixel 43 in the pixel array 42 of FIG. 2. For TOF measurements, the pixel 50 may operate as a time-resolving sensor, as discussed later with reference to FIGS. 5-10. As shown in FIG. 3, the pixel 50 may include a Photo Diode (PD) unit 52 electrically connected to an output unit 53. The PD unit 52 may include a first PD 55 connected in parallel with a second PD 56. The first PD 55 may be a very high conversion gain PD operable to convert received luminance (or incoming light)—illustrated by a line with the reference numeral “57”—into an electrical signal, which may be provided to the output unit 53 via a first PD-specific output terminal 58 for further processing. In some embodiments, the received luminance 57 may be the luminance received in the returned pulse 37 (FIG. 2). In particular embodiments, the conversion gain of the first PD 55 may be at least 400 μV per photoelectron (or photon), which also may be interchangeably referred as 400 μV/e−. As mentioned earlier, conventional PDs have conversion gain lower than 200 μV/e−. The high gain PD 55 also may have a much higher PDE—in the range of 45% or more, thereby facilitating photon detection in low light conditions as well. The PD 55 may perform photon counting without avalanche gain and, hence, can be used to replace a SPAD in DTOF LiDAR sensors. Furthermore, the PD 55 may be compatible with other low voltage Complementary Metal Oxide Semiconductor (CMOS) circuits and may operate at “conventional” supply voltage of around 2.5V to 3V, thereby providing significant power savings. In contrast, as mentioned before, a SPAD (or an APD) may require a high operating voltage of around 20V to 30V. Thus, the pixel 50 comprising the PD 55 with high conversion gain, high PDE, and low operating voltage may be advantageously used in a pixel array, such as the pixel array 42 in FIG. 2, in a high speed 3D imaging system—such as, for example, the system 15 in FIGS. 1-2—for all-weather autonomous navigation and other applications requiring TOF-based range measurements.

In one embodiment, the second PD 56 may be similar to the first PD 55 in the sense that the second PD 56 also may be a low-voltage PD with a very high gain and high PDE. However, in contrast to the first PD 55, the second PD 56 may not be exposed to light—as illustrated by a grey circle around the PD 56 in FIG. 3. Thus, the second PD 56 may detect the level of darkness—for example, at the time of reception of luminance 57—and generate a reference signal (or dark current) representing the darkness level. The reference signal may be provided to the output unit 53 via a second PD-specific output terminal 59. It is noted that, although only one high gain PD 55 is shown in the PD unit 52 as a light receptor, in some embodiments, the PD unit 52 may include more than one PDs similar to the PD 55; all such high gain PDs may be connected in parallel with each other (and with the unexposed PD 56) and exposed to received light.

It is noted here that, simply for ease of discussion and depending on the context, the same reference numeral may be used in the discussion of FIGS. 3-10 to occasionally interchangeably refer to a line/terminal and the signal associated with that line/terminal. For example, the reference numeral “58” may be used to interchangeably refer to the electrical signal generated by the PD 55 and the line/terminal carrying the electrical signal. Similarly, the reference numeral “59” may be used to refer to the reference signal generated by the PD 56 and the line/terminal carrying the reference signal, the reference numeral “74” (discussed later below) may be used to refer to the electrical signal output by the PD unit 68 (FIG. 4) and the line/terminal carrying the electrical signal, and so on.

An amplifier unit 60 in the output unit 53 may be connected in series with the PDs 55-56, and may be operable to amplify the electrical signal 58. In some embodiments, the amplifier unit 60 may be a sense amplifier. Prior to such amplification, the sense amplifier 60 may reset the PDs 55-56. Thereafter, the PD 55 may receive the luminance 57 and generate the electrical signal 58. The sense amp 60 may operate to amplify the electrical signal only when an electronic shutter is turned on. Exemplary shutter signals are shown in FIGS. 6, 8, and 10, which are discussed later. In the embodiment of FIG. 3, a shutter signal (also referred to as an “electronic shutter”) 61 is shown as an externally-supplied “Enable” (En) input to the sense amplifier 60. In one embodiment, the PDs 55-56 may be reset before the shutter signal 61 is turned on. While the shutter signal 61 is active, the sense amp 60 may sense the electrical signal 58 (generated in response to detection of photon arrival) vis-à-vis the reference signal (or dark current) 59 and amplify the electrical signal to generate an intermediate output 62. In one embodiment, the sense amp 60 may be a conventional current sense amplifier. The intermediate output 62 may be a voltage signal or a current signal, depending on implementation.

Exemplary circuit details for the Time-to-Charge Converter (TCC) unit 64 are shown in FIGS. 5, 7, and 9, discussed later below. The TCC unit 64 may be used to record the photon arrival time based on analog charge transfer (discussed later). Generally, in particular embodiments, the TCC unit 64 may include a pixel-specific device—such as a Pinned Photo Diode (PPD) or a capacitor—operable to store an analog charge, and a control circuit coupled to the device and operable to: (i) initiate transfer of a portion of the analog charge from the device, (ii) terminate the transfer in response to receipt of the intermediate output 62 within a pre-defined time interval, and (iii) generate a pixel-specific analog output (PIXOUT) 65 for the pixel based on the portion of the analog charge transferred. In the embodiment of FIG. 2, the pixout signals from various pixels 43 (similar to the pixel 50 in FIG. 3) in the image sensor array 42 may be processed by the image processing unit 46 (or the processor 19) to record the photon arrival time(s) and determine TOF values. Thus, as discussed in more detail later, the intermediate output 62 (and, hence, the photon detection by the PD 55) may control the charge transfer from the analog storage device (for example, a PPD or a capacitor) to generate the pixel-specific output (Pixout) 65. As also discussed later, the charge transfer may facilitate recording of a TOF value and corresponding range of the 3D object 26. In other words, the output from the PD 55 is used to determine the operation of the storage device. Furthermore, in the pixel 50, the light-sensing functionality is performed by the PD 55, whereas the analog storage device is used as a time-to-charge converter instead of a light-sensing element.

FIG. 4 shows exemplary circuit details of another pixel 67 according to some embodiments of the present disclosure. The pixel 67 is another example of the pixel 43 in the pixel array 42 of FIG. 2. Like the pixel 50 in FIG. 3, the pixel 67 also may operate as a time-resolving sensor for TOF measurements, as discussed later with reference to FIGS. 5-10. As shown in FIG. 4, the pixel 50 may include a Photo Diode (PD) unit 68 electrically connected to an output unit 69. In the embodiment of FIG. 4, the PD unit 68 may include only one PD 70 with a very high conversion gain and high PDE; an unexposed PD, like the PD 56, may not be included as part of the PD unit 68. The PD 70, however, may be substantially similar to the PD 55 (FIG. 3) and, hence, earlier discussion of gain, operating voltage, and PDE of the PD 55 applies to the PD 70 as well. Therefore, such earlier discussion is not repeated here for the sake of brevity. It is noted that, although only one high gain PD 70 is shown in the PD unit 68 as a light receptor, in some embodiments, the PD unit 68 may include more than one PDs similar to the PD 70; all such high gain PDs may be connected in parallel with each other and exposed to received light.

As shown in FIG. 4, the PD 70 may be operable to receive the incoming light/luminance 71 and may be connected to the generic supply voltage VDD (which may be in the range of 2.5 volts to 3 volts) via a switch 73. As before, the incoming light 71 may represent the luminance received in the returned pulse 37 (FIG. 2). The PD unit 68 may include a coupling capacitor 72 through which the electrical signal generated by the PD 70 upon detection of one or more photons in the received luminance 71 may be provided to the output unit 69 via the line/terminal 74. In the embodiment of FIG. 4, a gainstage circuit in the output unit 69 may be used as an amplifier unit to amplify the electrical signal 74. In the embodiment of FIG. 4, the gainstage circuit may include an inverting amplifier (or diode inverter) 75 in parallel with a bypass capacitor 76, as shown. In other embodiments, a non-inverting amplifier may be used instead, depending on the subsequent signal processing. A switch 77 may be provided to reset the gainstage prior to amplification of the electrical signal 74. The switches 73 and 77 may be controlled by an externally-supplied shutter signal, such as the electronic shutter signal 61 mentioned in the context of FIG. 3 earlier. Exemplary shutter signals are shown in FIGS. 6, 8, and 10, which are discussed later. When the shutter signal 61 is off (or not turned on), the switches 73, 77 may remain closed, thereby resetting the PD 70 and the gainstage. The gainstage may operate to amplify the electrical signal 74 only when the electronic shutter 61 is turned on. When the shutter signal 61 is turned on (or active), the switches 73, 77 are opened. If the PD 70 receives the luminance 71 and generates the electrical signal 74 while the shutter 61 is active, the gainstage may amplify the electrical signal 74 to generate an intermediate output 78. The intermediate output 78 may be a voltage signal or a current signal, depending on implementation.

Exemplary circuit details for the TCC unit 79 are shown in FIGS. 5, 7, and 9, discussed later below. Like the TCC unit 64 in FIG. 3, the TCC unit 79 in FIG. 4 also may be used to record the photon arrival time based on analog charge transfer. In certain embodiments, the TCC units 64 and 79 may be identical in construction. Generally, in particular embodiments, the TCC unit 79 may include a pixel-specific device—such as a PPD or a capacitor—operable to store an analog charge, and a control circuit coupled to the device and operable to: (i) initiate transfer of a portion of the analog charge from the device, (ii) terminate the transfer in response to receipt of the intermediate output 78 within a pre-defined time interval, and (iii) generate a pixel-specific analog output (PIXOUT) 80 for the pixel based on the portion of the analog charge transferred. In the embodiment of FIG. 2, the pixout signals from various pixels 43 (similar to the pixel 67 in FIG. 4) in the image sensor array 42 may be processed by the image processing unit 46 (or the processor 19) to record the photon arrival time(s) and determine TOF values. Thus, as discussed in more detail later, the intermediate output 78 (and, hence, the photon detection by the PD 70) may control the charge transfer from the analog storage device (for example, a PPD or a capacitor) to generate the pixel-specific output (Pixout) 80. As also discussed later, the charge transfer may facilitate recording of a TOF value and corresponding range of the 3D object 26. In other words, the output from the high gain PD 70 is used to determine the operation of the analog storage device. Furthermore, in the pixel 67, the light-sensing functionality is performed by the PD 70, whereas the analog storage device is used as a time-to-charge converter instead of a light-sensing element.

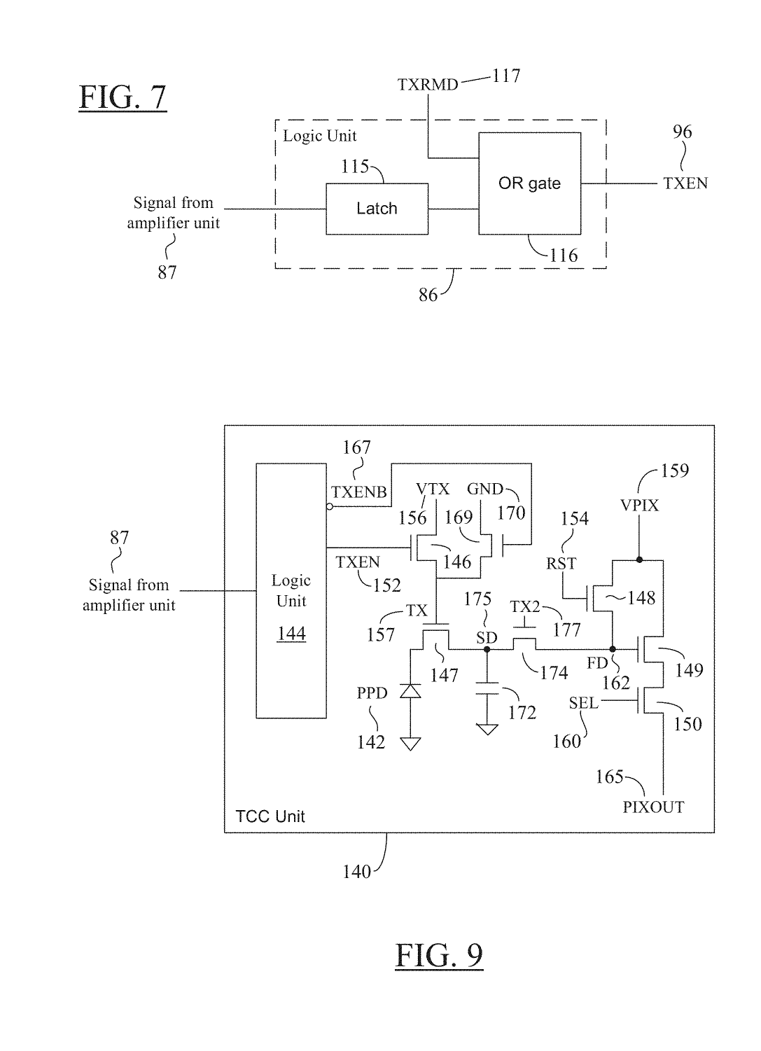

FIG. 5 provides circuit details of an exemplary TCC unit 84 in a pixel as per particular embodiments of the present disclosure. The pixel may be any of the pixels 50 or 67 (which are examples of the more generic pixel 43 in FIG. 2), and the TCC unit 84 may be any of the TCC units 64 or 79. An electronic shutter signal, such as the shutter signal 61 in FIGS. 3-4, may be provided to each pixel (as discussed in more detail later with reference to the timing diagrams in FIGS. 6, 8, and 10) to enable the pixel to capture the pixel-specific photoelectrons in the received light. More generally, the TCC unit 84 may be considered to have a charge transfer trigger portion, a charge generation and transfer portion, and a charge collection and output portion. The charge transfer trigger portion may include a logic unit 86 that receives the signal 87 from the relevant amplifier unit—the sense amplifier 60 in case of the pixel 50 in FIG. 3 or the gainstage in case of the pixel 67 in FIG. 4. The signal 87 may represent either of the intermediate outputs 62 and 78, as applicable. Block diagram of an exemplary logic unit, such as the logic unit 86, is shown in FIG. 7, which is discussed later. The charge generation and transfer portion may include a PPD 89, a first N-channel Metal Oxide Semiconductor Field Effect Transistor (NMOSFET or NMOS transistor) 90, a second NMOS transistor 91, and a third NMOS transistor 92. The charge collection and output portion may include the third NMOS transistor 92, a fourth NMOS transistor 93, and a fifth NMOS transistor 94. It is noted here that, in some embodiments, the TCC unit 84 in FIG. 5 and the TCC unit 140 in FIG. 9 (discussed later) may be formed of P-channel Metal Oxide Semiconductor Field Effect Transistors (PMOSFETs or PMOS transistors) or other different types of transistors or charge transfer devices. Furthermore, the above-mentioned separation of various circuit components into respective portions is for illustrative and discussion purpose only. In certain embodiments, such portions may include more or less or different circuit elements than those listed here.

The PPD 89 may store analog charge similar to a capacitor. In one embodiment, the PPD 89 may be covered and does not respond to light. Thus, the PPD 89 may be used as a time-to-charge converter instead of a light sensing element. However, as noted before, the light-sensing functionality may be accomplished through the high gain PD 55 or 70. In certain embodiments, a photogate, a capacitor, or other semiconductor device—with suitable circuit modifications—may be used as a charge storage device instead of a PPD in the TCC units of FIGS. 5 and 9.

Under the operative control of the electronic Shutter signal 61, the charge transfer trigger portion—such as the logic unit 86—may generate a Transfer Enable (TXEN) signal 96 to trigger the transfer of charge stored in the PPD 89. A PD 55, 70 may detect a photon (which may be referred to as a “photon detection event”) in the light pulse that was transmitted and reflected off of an object, such as the object 26 in FIG. 2, and output the electrical signal 87, which may be latched by the logic unit 86, which may include logic circuits to process the electrical signal 87 to generate the TXEN signal 96 as discussed later in the context of FIG. 7.

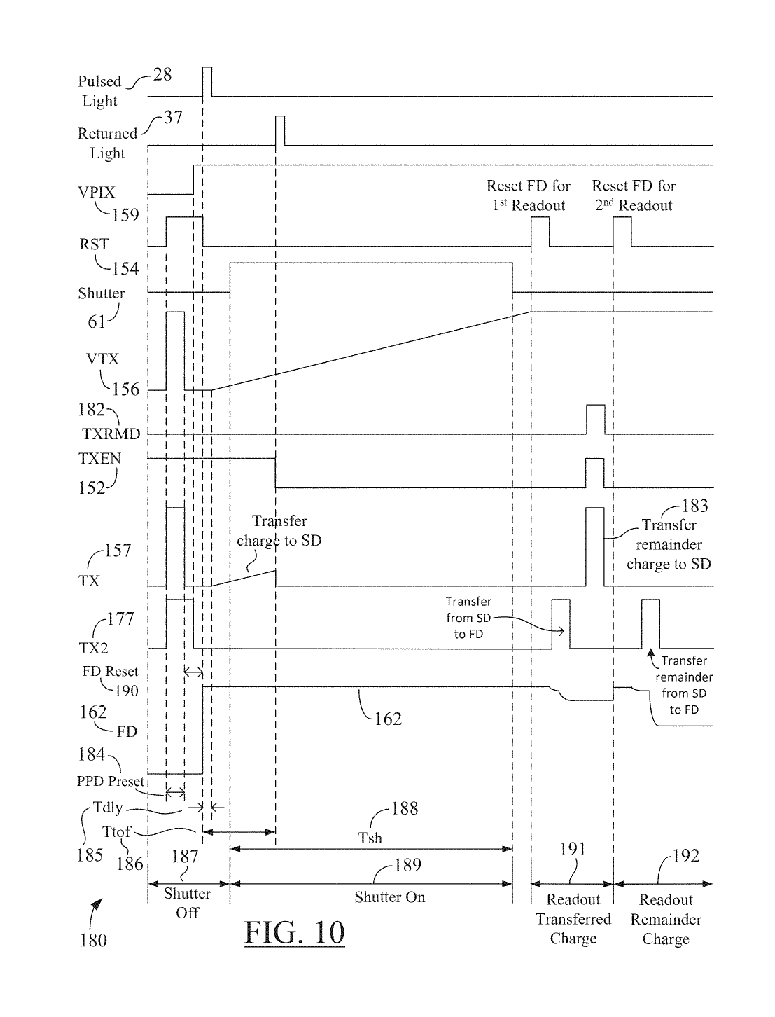

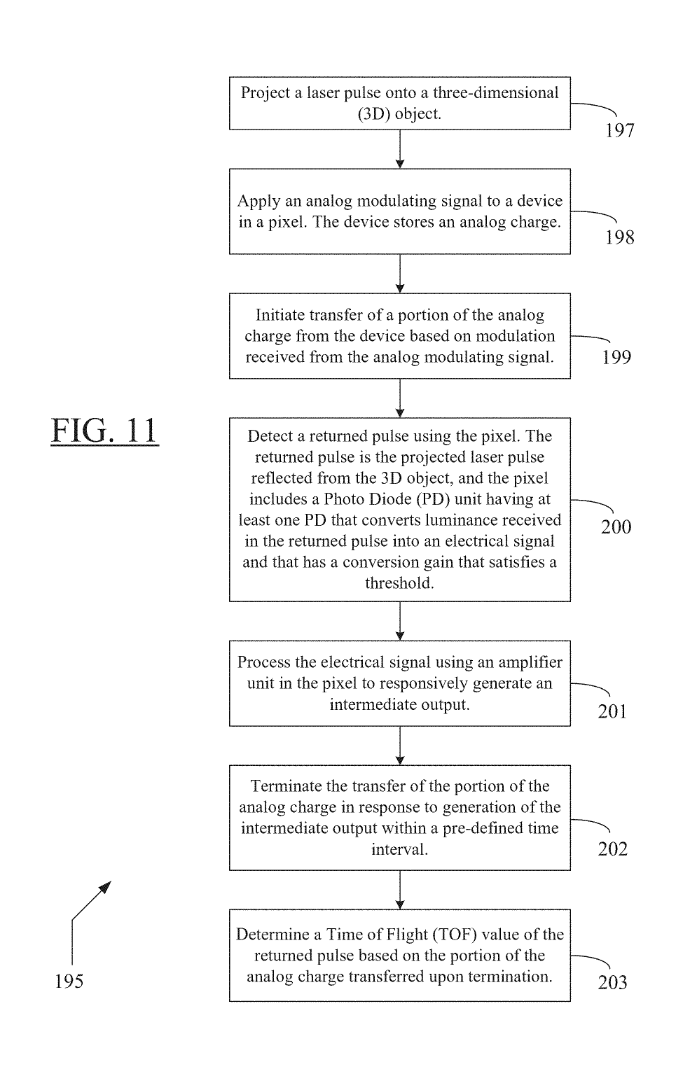

In the charge generation and transfer portion, the PPD 89 may be initially set to its full well capacity using a Reset (RST) signal 98 in conjunction with the third transistor 92. The first transistor 90 may receive a Transfer Voltage (VTX) signal 99 at its drain terminal and the TXEN signal 96 at its gate terminal. A TX signal 100 may be available at the source terminal of the first transistor 90 and applied to the gate terminal of the second transistor 91. As shown, the source terminal of the first transistor 90 may be connected to the gate terminal of the second transistor 91. As discussed later below, the VTX signal 99 (or, equivalently, the TX signal 100) may be used as an analog modulating signal to control the analog charge to be transferred from the PPD 89, which may be connected to the source terminal of the transistor 91 in the configuration shown. The second transistor 91 may transfer the charge on the PPD 89 from its source terminal to its drain terminal, which may connect to the gate terminal of the fourth transistor 93 and form a charge “collection site” referred to as a Floating Diffusion (FD) node/junction 102. In particular embodiments, the charge transferred from the PPD 89 may depend on the modulation provided by the analog modulating signal 99 (or, equivalently, the TX signal 100). In the embodiments of FIGS. 5 and 10, the charge transferred is electrons. However, the present disclosure is not limited thereto. In an embodiment, a PPD with different design may be used, where the charge transferred may be holes.

In the charge collection and output portion, the third transistor 92 may receive the RST signal 98 at its gate terminal and a Pixel Voltage (VPIX) signal 104 at its drain terminal. The source terminal of the third transistor 92 may be connected to the FD node 102. In one embodiment, the voltage level of the VPIX signal 104 may equal to the voltage level of the generic supply voltage VDD and may be in the range of 2.5V (volts) to 3V. The drain terminal of the fourth transistor 93 also may receive the VPIX signal 104 as shown. In particular embodiments, the fourth transistor 93 may operate as an NMOS source follower to function as a buffer amplifier. The source terminal of the fourth transistor 93 may be connected to the drain terminal of the fifth transistor 94, which may be in cascode with the source follower 93 and receiving a Select (SEL) signal 105 at its gate terminal. The charge transferred from the PPD 89 and “collected” at the FD node 102 may appear as the pixel-specific output PIXOUT 107 at the source terminal of the fifth transistor 94. The Pixout line/terminal 107 may represent either of the Pixout lines 65 (FIG. 3) or 80 (FIG. 4).

Briefly, as mentioned before, the charge transferred from the PPD 89 to FD 102 is controlled by the VTX signal 99 (and, hence, the TX signal 100). The amount of charge reaching the FD node 102 is modulated by the TX signal 100. In one embodiment, the voltage VTX 99 (and, also TX 100) may be ramped to gradually transfer charge from the PPD 89 to FD 102. Thus, the amount of charge transferred may be a function of the analog modulating voltage TX 100, and the ramping of the TX voltage 100 is a function of time. Hence, the charge transferred from the PPD 89 to the FD node 102 also is a function of time. If, during the transfer of charge from the PPD 89 to FD 102, the second transistor 91 is turned off (for example, becomes open-circuited) due to the generation of the TXEN signal 96 by the logic unit 86 upon a photon detection event for the PD 55 (or 70), the transfer of charge from the PPD 89 to the FD node 102 stops. Consequently, the amount of charge transferred to FD 102 and the amount of charge remaining in the PPD 89 are both a function of the TOF of the incoming photon(s). The result is a time-to-charge conversion and a single-ended to differential signal conversion. The PPD 89 thus operates as a time-to-charge converter. The more the charge is transferred to the FD node 102, the more the voltage decreases on the FD node 102 and the more the voltage increases on the PPD 89. It is observed that the farther the object 26 (FIG. 2), the more the charge will be transferred to the FD node 102.

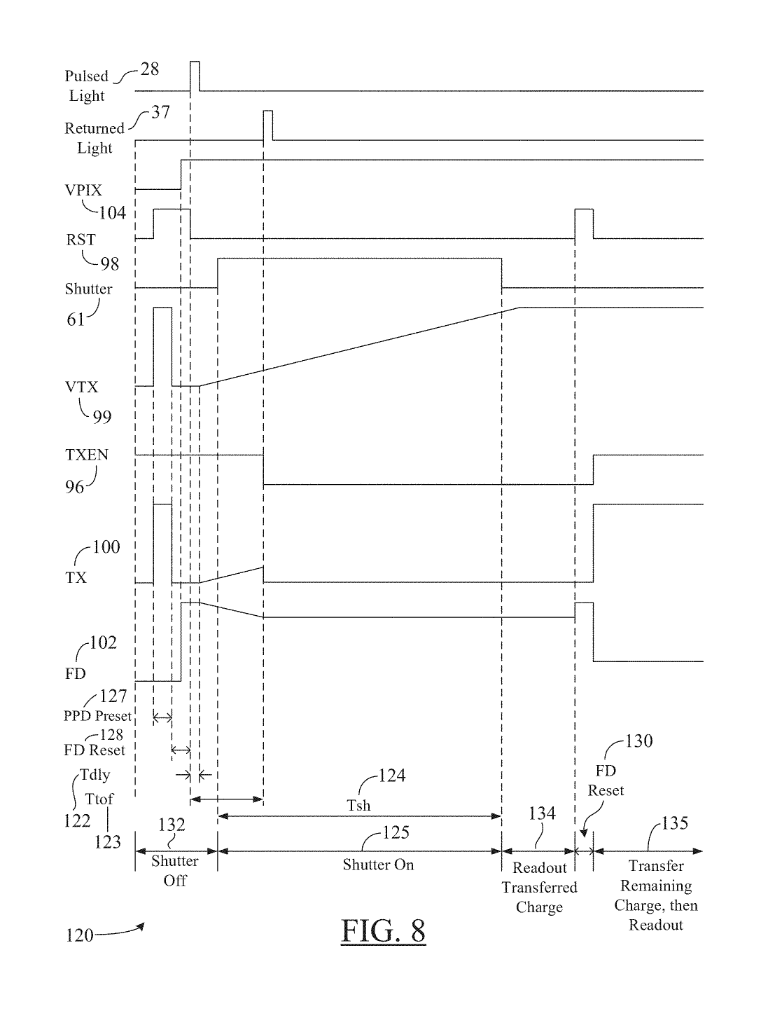

The voltage at the floating diffusion 102 may be later transferred as the Pixout signal 107 to an Analog-to-Digital Converter (ADC) unit (not shown) using the transistor 94 and converted into an appropriate digital signal/value for subsequent processing. More details of the timing and operation of various signals in FIG. 5 are provided below with reference to discussion of FIG. 8. In the embodiment of FIG. 5, the fifth transistor 94 may receive the SEL signal 105 for selecting the corresponding pixel 50 (or 67) to readout the charge in the floating diffusion (FD) 102 as a PIXOUT1 (or Pixel Output 1) voltage and the remaining charge in the PPD 89 as a PIXOUT2 (or Pixel Output 2) voltage after it is completely transferred to the FD node 102, wherein the FD node 102 converts a charge on it to a voltage and the pixel output line (PIXOUT) 107 sequentially outputs PIXOUT1 and PIXOUT2 signals as discussed later with reference to FIG. 8. In another embodiment, either the PIXOUT1 signal or the PIXOUT2 signal (but not both) may be read out.

In one embodiment, the ratio of one pixel output (for example, PIXOUT1) to the sum of the two pixel outputs (here, PIXOUT1+PIXOUT2) may be proportional to the time difference of “T_{tof}” and “T_{dly}” values, which are shown, for example, in FIG. 8 and discussed in more detail later below. In case of the pixel 50 (or 67), for example, the “T_{tof}” parameter may be a pixel-specific TOF value of a light signal received by the PD 55 (or the PD 70) and the delay time parameter “T_{dly}” may be the time from when the light signal 28 was initially transmitted until the VTX signal 99—in the TCC unit 64 (or the TCC unit 79)—starts to ramp. The delay time (T_{dly}) may be negative when the light pulse 28 is transmitted after VTX 99 starts to ramp (which may typically occur when the electronic shutter 61 is “opened”). The above-mentioned proportionality relation may be represented by the following equation:

$$\frac{Pixout 1}{Pixout 1 + Pixout 2} ∝ ( {T}_{tof} - {T}_{dly} ) \qquad ( 1 )$$

However, the present disclosure is not limited to the relationship present in equation (1). As discussed below, the ratio in equation (1) may be used to calculate depth or distance of a 3D object, and is less sensitive to pixel-to-pixel variations when Pixout1+Pixout2 is not always the same.

For ease of reference, the term “P1” may be used to refer to “Pixout1” and the term “P2” may be used to refer to “Pixout2” in the discussion below. It is seen from the relationship in equation (1) that the pixel-specific TOF value may be determined as a ratio of the pixel-specific output values P1 and P2. In certain embodiments, once the pixel-specific TOF value is so determined, the pixel-specific distance (“D”) or range (“R”) to an object (such as the 3D object 26 in FIG. 2) or a specific location on the object may be given by:

$$D = {T}_{tof} * \frac{c}{2} \qquad ( 2 )$$

where the parameter “c” refers to the speed of light. Alternatively, in some other embodiments where the modulating signal—such as the VTX signal 99 (or the TX signal 100) in FIG. 5, for example—is linear inside a shutter window, the range/distance may be computed as:

$$D = \frac{c}{2} * [ ( ( \frac{{P}_{1}}{{P}_{1} + {P}_{2}} ) * {T}_{shutter} ) + {T}_{dly} ] \qquad ( 3 )$$

In equation (3), the parameter “Tₛₕᵤₜₜₑᵣ” is the shutter duration or shutter “ON” period. The parameter “Tₛₕᵤₜₜₑᵣ” is referred to as the parameter “Tₛₕ” in the embodiments of FIGS. 8 and 10. Consequently, a 3D image of the object—such as the object 26—may be generated by the TOF system 15 based on the pixel-specific range values determined as given above.

In view of the present disclosure's analog modulation-based manipulation or control of the PPD charge distribution inside a pixel itself, the range measurement and resolution are also controllable. The pixel-level analog amplitude modulation of the PPD charge may work with an electronic shutter that may be a global shutter as, for example, in a Charge Coupled Device (CCD) image sensor. The global shutter may allow for a better image capture of a fast-moving object (such as a vehicle), which may be helpful in a driver assistant system or an autonomous navigation system. Furthermore, although the disclosure herein is primarily provided in the context of a one-pulse TOF imaging system, like the system 15 in FIGS. 1-2, the principles of pixel-level internal analog modulation approach discussed herein may be implemented, with suitable modifications (if needed), in a continuous wave modulation TOF imaging system or a non-TOF system as well.

FIG. 6 is an exemplary timing diagram 109 that provides an overview of the modulated charge transfer mechanism in the TCC unit 84 of FIG. 5 according to one embodiment of the present disclosure. The waveforms shown in FIG. 6 (and also in FIGS. 8 and 10) are simplified in nature and are for illustrative purpose only; the actual waveforms may differ in timing as well as shape depending on the circuit implementation. The signals common between FIGS. 5 and 6 are identified using the same reference numerals for ease of comparison. These signals include the VPIX signal 104, the RST signal 98, the electronic SHUTTER signal 61, and the VTX modulating signal 99. Two additional waveforms 111-112 are also shown in FIG. 6 to illustrate the status of the charge in PPD 89 and that in the FD 102, respectively, when modulating signal 99 is applied during charge transfer. In the embodiment of FIG. 6, VPIX 104 may start as a low logic voltage (for example, logic 0 or 0 volts) to initialize the pixel 50 (or 67) and switch to a high logic voltage (for example, logic 1 or 3 volts (3V)) during operation of the pixel 50 (or 67). RST 98 may start with a high logic voltage pulse (for example, a pulse that goes from logic 0 to logic 1 and back to logic 0) during the initialization of the pixel 50 (or 67) to set the charge in the PPD 89 to its full well capacity and set the charge in the FD 102 to zero Coulombs (0 C). The reset voltage level for FD 102 may be a logic 1 level. During a range (TOF) measurement operation, the more electrons the FD 102 receives from the PPD 89, the lower the voltage on the FD 102 becomes. The Shutter signal 61 may start with a low logic voltage (for example, logic 0 or 0V) during the initialization of the pixel 50 (or 67), switch to a logic 1 level (for example, 3 volts) at a time that corresponds to the minimum measurement range during operation of the pixel 50 (or 67) to enable the PD 55 (or 70) to detect the photon(s) in the returned light pulse 37 (represented as the incoming light signal 57 in FIG. 3 and the incoming light signal 71 in FIG. 4), and then switch to a logic 0 level (for example, 0V) at a time that corresponds to the maximum measurement range. Thus, the duration of the logic 1 level of the shutter signal 61 may provide a pre-defined time interval/window to receive the output from the PD 55 (or 70). The charge in the PPD 89 starts out fully charged during initialization (when VPIX 104 is low, RST 98 is high, and VTX 99 is high to fill the charge in the PPD 89) and decreases as VTX 99 is ramped from 0V to a higher voltage, preferably in a linear fashion. The PPD charge level under the control of the analog modulating signal 99 is illustrated by waveform with reference numeral “111” in FIG. 6. The PPD charge decrease may be a function of how long VTX ramps, which results in a transfer of a certain amount of charge from the PPD 89 to the FD 102. Thus, as shown by the waveform with reference numeral “112” in FIG. 6, a charge in FD 102 starts out at a low charge (for example, 0 C) and increases as VTX 99 is ramped from 0V to a higher voltage, which partially transfers a certain amount of charge from the PPD 89 to the FD 102. This charge transfer is a function of how long VTX 99 ramps.

As noted before, the pixel-specific output (PIXOUT) 107 in FIG. 5 is derived from the PPD charge transferred to the floating diffusion node 102. Thus, the Pixout signal 107 may be considered as amplitude-modulated over time by the analog modulating voltage VTX 99 (or, equivalently, the TX voltage 100). In this manner, the TOF information is provided through Amplitude Modulation (AM) of the pixel-specific output 107 using the modulating signal VTX 99 (or, equivalently, the TX signal 100). In particular embodiments, the modulating function for generating the VTX signal 99 may be monotonic. In the exemplary embodiments of FIGS. 6, 8, and 10, the analog modulating signals may be generated using a ramp function and, hence, they are shown as having ramp-type waveforms. However, in other embodiments, different types of analog waveforms/functions may be used as modulating signals.

FIG. 7 shows the block diagram of an exemplary logic unit 86 that may be used in the TCC unit 84 of FIG. 5 as per particular embodiments of the present disclosure. The logic unit 86 may include a latch 115 and a two-input OR gate 116. While the shutter signal 61 is active or turned “on”, the latch 115 may receive the signal 87 from the relevant amplifier unit (for example, the sense amplifier's intermediate output 62 or the gainstage's intermediate output 78) and may output a signal that goes from logic 1 to logic 0 and remains at logic 0. In other words, the latch 115 converts the amplifier-provided signal 87—which is generated as a result of a photon detection event by the PD 55 or the PD 70, as applicable—to a signal that goes from logic 1 to logic 0 and remains at logic 0, at least during the shutter ON period. In particular embodiments, the latch output may be triggered by the first edge of the signal 87. The first edge may be positive-going or negative-going depending on the circuit design.

The two-input logic OR gate 116 may include a first input connected to the output of the latch 115, a second input for receiving a signal (TXRMD) 117, and an output to provide the TXEN signal 96. In one embodiment, the TXRMD signal 117 may be generated internally within the relevant pixel 50 (or 67). The OR gate 116 may logically OR the output of the latch 115 with the TXRMD signal 117 to obtain the final TXEN signal 96. Such internally-generated signal may remain low while the electronic shutter is “on”, but may be asserted “high” so that the TXEN signal 96 goes to a logic 1 to facilitate the transfer of the remaining charge in the PPD 89 (at event 135 in FIG. 8, discussed below). In some embodiments, the TXRMD signal or a similar signal may be externally-supplied.

FIG. 8 is a timing diagram 120 that shows exemplary timing of different signals in the system 15 of FIGS. 1-2 when the TCC unit 84 in the embodiment of FIG. 5 is used in a pixel, such as the pixel 50 or the pixel 67, as part of a pixel array, such as the pixel array 42 in FIG. 2, for measuring TOF values according to certain embodiments of the present disclosure. Various signals—such as the transmitted pulse 28, the VPIX input 104, the TXEN input 96, and the like shown in the embodiments of FIGS. 2-5 are identified in FIG. 8 using the same reference numerals for the sake of consistency and ease of discussion. Prior to discussion FIG. 8, it is noted that, in the context of FIG. 8 (and also in case of FIG. 10), the parameter “T_{dly}” refers to the time delay between the rising edge of the projected pulse 28 and the time instance when the VTX signal 99 starts to ramp, as indicated by reference numeral “122”; the parameter “T_{tof}” refers to the pixel-specific TOF value as measured by the delay between the rising edges of the projected pulse 28 and the received (returned) pulse 37, as indicated by reference numeral “123”; and the parameter “Tₛₕ” refers to the time period between the “opening” and the “closing” of the electronic shutter—as indicated by reference numeral “124” and given by the assertion (for example, logic 1 or “on”) and de-assertion (or de-activation) (for example, logic 0 or “off”) of the shutter signal 61. Thus, the electronic shutter signal 61 is considered to be “active” during the period “Tₛₕ”, which is also identified using the reference numeral “125.” In some embodiments, the delay “T_{dly}” may be pre-determined and fixed regardless of operating conditions. In other embodiments, the delay “T_{dly}” may be adjustable at run-time depending on, for example, the external weather condition. It is noted here that the “high” or “low” signal levels relate to the design of the pixel 43 (which is represented by the pixel 50 or 67). The signal polarities or bias levels shown in FIG. 8 may be different in other types of pixel designs based on, for example, the types of transistors or other circuit components used.

As noted before, the waveforms shown in FIG. 8 (and also in FIG. 10) are simplified in nature and are for illustrative purpose only; the actual waveforms may differ in timing as well as shape depending on the circuit implementation. As shown in FIG. 8, the returned pulse 37 may be a time-wise delayed version of the projected pulse 28. In particular embodiments, the projected pulse 28 may be of a very short duration such as, for example, in the range of 5 to 10 nanoseconds (ns). The returned pulse 37 may be sensed using a high gain PD in the pixel 43—such as the pixel 55 in the pixel 50 or the PD 70 in the pixel 67. The electronic shutter 61 may “control” the capture of the pixel-specific photon(s) in the received light 37. The shutter signal 61 may have a gated delay—with reference to the projected pulse 28—to avoid the light scatters from reaching the pixel array 42. The light scatters of the projected pulse 28 may occur, for example, due to an inclement weather.

In addition to various external signals (for example, VPIX 104, RST 98, and the like) and internal signals (for example, TX 100, TXEN 96, and FD voltage 102), the timing diagram 120 in FIG. 8 also identifies the following events or time periods: (i) a PPD preset event 127 when RST, VTX, TXEN, and TX signals are high, while VPIX and SHUTTER signals are low; (ii) a first FD reset event 128 from when TX is low until RST turns from high to low; (iii) the delay time (T_{dly}) 122; (iv) the time of flight (T_{tof}) 123; (v) the electronic shutter “on” or “active” period (Tₛₕ) 124; and (vi) a second FD reset event 130 for the duration of when RST is a logic 1 for a second time. FIG. 8 also illustrates when the electronic shutter is “closed” or “off” initially (which is indicated by reference numeral “132”), when the electronic shutter is “open” or “on” (which is indicated by the reference numeral “125”), when the charge initially transferred to the FD node 102 is read out through PIXOUT 107 (which is indicated by reference numeral “134”), when the FD voltage is reset a second time at arrow 130, and when the remaining charge in PPD 89 is transferred to FD 102 and again readout at event 135 (for example, as output to PIXOUT 107). In one embodiment, the shutter “on” period (Tsh) may be less than or equal to the ramping time of VTX 99.

Referring to FIG. 8, in case of the TCC unit 84 in FIG. 5, the PPD 89 may be filled with charge to its full well capacity at an initialization stage (for example, the PPD Preset event 127). During the PPD preset time 127, the RST, VTX, TXEN, and TX signals may be high, whereas the VPIX and SHUTTER signals may be low, as shown. Then, the VTX signal 99 (and, hence, the TX signal 100) may go low to shut off the second transistor 91 and the VPIX signal 104 may go high to commence the charge transfer from the “fully-charged” PPD 89. In case of the electronic shutter 61 being a global shutter, in particular embodiments, all pixels in the pixel array 42 may be selected together at a time and all selected PPDs may be reset together using the RST signal 98. Each pixel may be read individually using the methodology similar to a frame transfer CCD or an inter-line transfer CCD. Each pixel-specific analog pixout signals (such as, for example, the pixout1 and pixout2 signals) may be sampled and converted to corresponding digital values—for example, the earlier-mentioned “P1” and “P2” values—by an ADC unit (not shown).

In the embodiment shown in FIG. 8, all signals—except the TXEN signal 96—start at logic 0 or “low” level as shown. Initially, as mentioned above, the PPD 89 is preset when RST, VTX, TXEN, and TX go to a logic 1 level, and VPIX stays low. Thereafter, the FD node 102 is reset while RST is a logic 1, when VTX and TX go to a logic 0 and VPIX goes to high (or a logic 1). For ease of discussion, the same reference numeral “102” is used to refer to the FD node in FIG. 5 and associated voltage waveform in the timing diagram of FIG. 8. After FD is reset to high (for example, 0 C in charge domain), VTX is ramped while TXEN is a logic 1. The time of flight (Ttof) duration 123 is from when the laser pulse 28 is transmitted until the returned pulse 37 is received, and is also the time during which charge is transferred partially from the PPD 89 to the FD 102. The VTX input 99 (and, hence, the TX input 100) may be ramped while the shutter 61 is “on” or “open”. This may cause an amount of charge in the PPD 89 to be transferred to the FD 102, which may be a function of how long VTX ramps. However, when the transmitted pulse 28 reflects off of the object 26 and is received by a PD—such as the PD 55 or the PD 70, depending on the pixel configuration, the generated amplified output—such as the intermediate output signal 62 or the intermediate output signal 78, as applicable—may be processed by the logic unit 86, which, in turn, may bring down the TXEN signal 96 to a static logic 0. Thus, detection of the returned pulse 37 by a PD 55 (or 70) in a temporally-correlated manner—that is, when the shutter is “on” or “active”—may be indicated by a logic 0 level for the TXEN signal 96. The logic low level of the TXEN input 96 turns off the first transistor 90 and the second transistor 91, which stops the transfer of charge to FD 102 from the PPD 89. When SHUTTER input 61 goes to a logic 0 and SEL input 105 (not shown in FIG. 8) goes to a logic 1, the charge in FD 102 is output as a voltage PIXOUT1 onto the PIXOUT line 107. Then, the FD node 102 may be reset again (as indicated at reference numeral “130”) with a logic high RST pulse 98. Thereafter, when the TXEN signal 96 goes to a logic 1, the remaining charge in the PPD 89 is substantially completely transferred to the FD node 102 and output as a voltage PIXOUT2 onto PIXOUT line 107. As mentioned earlier, the PIXOUT1 and PIXOUT2 signals may be converted into corresponding digital values P1 and P2 by an appropriate ADC unit (not shown). In certain embodiments, these P1 and P2 values may be used in equation (2) or equation (3) above to determine a pixel-specific distance/range between a pixel 43 (as represented, for example, by the pixel 50 or 67) and the 3D object 26.

FIG. 9 shows circuit details of another exemplary TCC unit 140 as per particular embodiments of the present disclosure. The TCC unit 140 may be any of the TCC units 64 or 79. In some embodiments, the TCC unit 140 may be used instead of the TCC unit 84 in FIG. 5. Although many signals and circuit components are similar between the TCC units 84 (FIG. 5) and 140 (FIG. 9), it does not imply that the TCC units in FIGS. 5 and 9 are identical or that they operate in an identical manner. In view of the earlier discussion of FIG. 5, only a brief discussion of the TCC unit 140 in FIG. 9 is provided to highlight its distinguishing aspects.

Like the TCC unit 84 in FIG. 5, the TCC unit 140 in FIG. 9 also includes a PPD 142, a logic unit 144, a first NMOS transistor 146, a second NMOS transistor 147, a third NMOS transistor 148, a fourth NMOS transistor 149, a fifth NMOS transistor 150; generates the internal input TXEN 152; receives external inputs RST 154, VTX 156 (and, hence, the TX signal 157), VPIX 159, and SEL 160; has an FD node 162; and outputs the PIXOUT signal 165. However, unlike the TCC unit 84 in FIG. 5, the TCC unit 140 in FIG. 9 also generates a second TXEN signal (TXENB) 167, which may be a complement of the TXEN signal 152 and may be supplied to the gate terminal of a sixth NMOS transistor 169. The sixth NMOS transistor 169 may have its drain terminal connected to the source terminal of the transistor 146 and its source terminal connected to a Ground (GND) potential 170. The TXENB signal 167 may be used to bring the GND potential to the gate terminal of the TX transistor 147. Without the TXENB signal 167, when the TXEN signal 152 goes low, the gate of the TX transistor 147 may be floating and the charge transfer from the PPD 142 may not be fully terminated. This situation may be ameliorated using the TXENB signal 167. Additionally, the TCC unit 140 also may include a Storage Diffusion (SD) capacitor 172 and a seventh NMOS transistor 174. The SD capacitor 172 may be connected at the junction of the drain terminal of the transistor 147 and the source terminal of transistor 174, and may “form” an SD node 175 at the junction. The seventh NMOS transistor 174 may receive at its gate terminal a different, second Transfer signal (TX2) 177 as an input. The drain of the transistor 174 may connect to the FD node 162 as illustrated.

The signals RST, VTX, VPIX, TX2, and SEL may be supplied to the TCC unit 140 from an external unit, such as, for example, the image processing unit 46 in FIG. 2. Furthermore, in certain embodiments, the SD capacitor 172 may not be an extra capacitor, but may be merely the junction capacitor of the SD node 175. In the TCC unit 140, the charge transfer trigger portion may include the logic unit 144; the charge generation and transfer portion may include the PPD 142, the NMOS transistors 146-148, 169, and 174, and the SD capacitor 172; and the charge collection and output portion may include the NMOS transistors 148-150. It is noted here that separation of various circuit components into respective portions is for illustrative and discussion purpose only. In certain embodiments, such portions may include more or less or different circuit elements than those listed here. It is further noted that, like the logic unit 86 in FIG. 7, the logic unit 144 also may receive the signal 87 from the relevant amplifier unit—the sense amplifier 60 in case of the pixel 50 in FIG. 3 or the gainstage in case of the pixel 67 in FIG. 4. The signal 87 may represent either of the intermediate outputs 62 and 78, as applicable. In certain embodiments, the logic unit 144 may be a modified version of the logic unit 86 in FIG. 7 to provide both the TXEN 152 and TXENB 167 outputs.

It is observed that the configuration of the TCC unit 140 in FIG. 9 is substantially similar to that of the TCC unit 84 in FIG. 5. Therefore, for the sake of brevity, the circuit portions and signals common between the embodiments in FIGS. 5 and 9—such as the transistors 146-150 and associated inputs like RST, SEL, VPIX, and so on—are not discussed here. It is observed that the TCC unit 140 in FIG. 9 may allow for a Correlated Double Sampling (CDS) based charge transfer. The CDS is a noise reduction technique for measuring an electrical value, such as a pixel/sensor output voltage (pixout), in a manner that allows removal of an undesired offset. In CDS, the output(s) of a pixel, such as the Pixout 165 in FIG. 9, may be measured twice—once in a known condition, and once in an unknown condition. The value measured from the known condition may be then subtracted from the value measured from the unknown condition to generate a value with a known relation to the physical quantity being measured—here, the PPD charge representing the pixel-specific portion of the received light. Using CDS, noise may be reduced by removing the reference voltage of the pixel (such as, for example, the pixel's voltage after it is reset) from the signal voltage of the pixel at the end of each charge transfer. Thus, in CDS, before the charge of a pixel is transferred as an output, the reset/reference value is sampled, which is then “deducted” from the value after the charge of the pixel is transferred.

In the embodiment of FIG. 9, the SD capacitor 172 (or the associated SD node 175) stores the PPD charge prior to its transfer to the FD node 162, thereby allowing the establishment (and sampling) of appropriate reset values at the FD node 162 prior to any charge is transferred to the FD node 162. As a result, each pixel-specific output (Pixout1 and Pixout2) may be processed by a CDS unit (not shown) in the image processing unit 46 (FIG. 2) to obtain a pair of pixel-specific CDS outputs. Subsequently, the pixel-specific CDS outputs may be converted to digital values—here, the P1 and P2 values mentioned earlier—by an ADC unit (not shown) in the image processing unit 46 (FIG. 2). The transistors 169 and 174, and the signals TXENB 167 and TX2 177 in FIG. 9 provide ancillary circuit components needed to facilitate CDS-based charge transfer. In one embodiment, the P1 and P2 values may be generated in parallel using, for example, an identical pair of ADC circuits. Thus, the differences between the reset levels and corresponding PPD charge levels of pixout1 and pixout2 signals may be converted to digital numbers by an ADC unit (not shown) and output as the pixel-specific signal values—P1 and P2—to enable the computation of the pixel-specific TOF value of the returned pulse 37 for the pixel 43 (as represented, for example, by pixels 50 or 67) based on the equation (1) given before. As noted earlier, such computation may be performed by the image processing unit 46 itself or by the processor 19 in the system 15. Consequently, a pixel-specific distance to the 3D object 26 (FIG. 2) also may be determined using, for example, equation (2) or equation (3). The pixel-by-pixel charge collection operation may be performed for all pixels in the pixel array 42. Based on all the pixel-specific distance or range values for the pixels 43 in the pixel array 42, a 3D image of the object 26 may be generated, for example, by the processor 19, and displayed on an appropriate display or user interface associated with the system 15. Furthermore, a 2D image of the 3D object 26 may be generated—for example, when no range values are calculated or when a 2D image is desired despite the availability of range values by simply adding the P1 and P2 values. In particular embodiments, such a 2D image simply may be a grayscale image, for example, when an IR laser is used.

It is observed here that the pixel configurations shown in FIGS. 3-4 as well as the TCC configurations shown in FIGS. 5 and 9 are exemplary only. As mentioned before, pixels with multiple, high-gain PDs also may be used to implement the teachings of the present disclosure. Similarly, a non-PPD based TCC unit also may be selected for a pixel (such as the pixel 43 in FIG. 2) as per teachings of the present disclosure. Furthermore, in some embodiments, the TCC units may have a single output (such as the PIXOUT lines 107, 165 in the embodiments of FIGS. 5 and 9, respectively) or, in other embodiments, the TCC units may have dual outputs where Pixout1 and Pixout2 signals may be output through different output lines (not shown). It is noted here that the pixel configurations 50, 67 discussed herein may be CMOS configurations. In other words, each pixel-specific PD unit, amplifier unit, and TCC unit may be a CMOS portion. As a result, DTOF measurements and range detection operations may be performed at a substantially lower voltage and higher PDE than the existing SPAD or APD based systems.

FIG. 10 is a timing diagram 180 that shows exemplary timing of different signals in the system 15 of FIGS. 1-2 when the TCC unit 140 in the embodiment of FIG. 9 is used in a pixel, such as the pixel 50 or the pixel 67, as part of a pixel array, such as the pixel array 42 in FIG. 2, for measuring TOF values according to certain embodiments of the present disclosure. The timing diagram 180 in FIG. 10 is similar to the timing diagram 120 in FIG. 8—especially with reference to the waveforms of VTX, Shutter, VPIX, and TX signals, and identification of various timing intervals or events such as, for example, the PPD preset event, the shutter “on” period, the time delay period (T_{dly}), and so on. Because of the earlier extensive discussion of the timing diagram 120 in FIG. 8, only a brief discussion of the distinguishing features in the timing diagram 180 in FIG. 10 is provided for the sake of brevity.

In FIG. 10, for the sake of consistency and ease of discussion, various externally-supplied signals—such as the VPIX signal 159, the RST signal 154, the electronic shutter signal 61, the analog modulating signal VTX 156, and the TX2 signal 177—and the internally-generated TXEN signal 152 are identified using the same reference numerals as those used for these signals in FIG. 9. Similarly, for ease of discussion, the same reference numeral “162” is used to refer to the FD node in FIG. 9 and associated voltage waveform in the timing diagram of FIG. 10. A Transfer Mode (TXRMD) signal 182 is shown in FIG. 10 (and a similar signal is also mentioned in FIG. 7), but not shown in FIG. 9 or in the earlier timing diagram of FIG. 8. In particular embodiments, the TXRMD signal 182 may be internally generated by the logic unit 144 or externally-supplied to the logic unit 144, for example, by the image processing unit 46 (FIG. 2). Like the logic unit 86 in FIG. 7, in one embodiment, the logic unit 144 may include logic circuits (not shown) to generate an output and then logically OR the output with an internally-generated signal—such as, for example, the TXRMD signal 182—to obtain the final TXEN signal 152. As shown in FIG. 10, in one embodiment, such internally-generated TXRMD signal 182 may remain low while the electronic shutter is “on”, but may be asserted “high” thereafter so that the TXEN signal 152 goes to a logic 1 to facilitate the transfer of the remaining charge in the PPD 142 (at event 183 in FIG. 10).

It is noted that the PPD preset event 184, the delay time (T_{dly}) 185, the TOF period (T_{tof}) 186, the shutter “off” interval 187, and the shutter “on” or “active” period (Tₛₕ) 188 or 189, and the FD reset event 190 in FIG. 10 are similar to corresponding events or time periods shown in FIG. 8. Therefore, additional discussion of these parameters is not provided for the sake of brevity. Initially, the FD reset event 190 results in the FD signal 162 going “high”, as shown. The SD node 175 is reset to “high” after the PPD 142 is preset to “low”. More specifically, during the PPD preset event 184, the TX signal 157 may be “high”, the TX2 signal 177 may be “high”, the RST signal 154 may be “high”, and the VPIX signal 159 may be “low” to fill electrons to PPD 142 and preset it to zero volt. Thereafter, the TX signal 157 may go “low” but the TX2 signal 177 and the RST signal 154 may briefly remain “high”, which, along with a “high” VPIX signal 159, may reset the SD node 175 to “high” and remove electrons from the SD capacitor 172. In the meantime, the FD node 162 is reset as well (following the FD reset event 190). The voltage at the SD node 175 or the SD reset event are not shown in FIG. 10.

In contrast to the embodiment in FIGS. 6 and 8, the PPD charge is amplitude modulated and initially transferred to the SD node 175 (through the SD capacitor 172) in the embodiment of FIGS. 9-10 when the electronic shutter 61 is “active” and the VTX signal 156 is ramped up—as noted on the TX waveform 157. Upon detection of photons by the high-gain PD—such as the PD 55 or the PD 70, as applicable—during the shutter “on” period 189, the TXEN signal 152 goes “low” and the initial charge transfer from the PPD 142 to the SD node 175 stops. The transferred charge stored at the SD node 175 may be read out on the Pixout line 165 (as a Pixout1 output) during the first readout period 191. In the first readout period 191, the RST signal 154 may be briefly asserted “high” after the electronic shutter 61 is de-activated or turned “off” to reset the FD node 162. Thereafter, the TX2 signal 177 may be pulsed “high” to transfer the charge from the SD node 175 to the FD node 162 while TX2 is “high”. The FD voltage waveform 162 illustrates this charge transfer operation. The transferred charge then may be readout (as Pixout1 voltage) during the first readout period 191 via the Pixout line 165 using the SEL signal 160 (not shown in FIG. 10).

During the first readout interval 191, after the initial charge is transferred from the SD node to the FD node and the TX2 signal 177 returns to the logic “low” level, the TXRMD signal 182 may be asserted (pulsed) “high” to generate a “high” pulse on the TXEN input 152, which, in turn, may generate a “high” pulse on the TX input 157 to allow transfer of the remaining charge in the PPD 142 to the SD node 175 (through the SD capacitor 172)—as indicated by the reference numeral “183” in FIG. 10. Thereafter, the FD node 162 may be reset again when the RST signal 154 is briefly asserted “high” again. The second RST high pulse may define a second readout period 192, in which the TX2 signal 177 may be pulsed “high” again “to transfer the PPD's remainder charge (at event 183) from the SD node 175 to the FD node 162 while TX2 is “high”. The FD voltage waveform 162 illustrates this second charge transfer operation. The transferred remaining charge then may be readout (as Pixout2 voltage) during the second readout period 192 via the Pixout line 165 using the SEL signal 160 (not shown in FIG. 10). As mentioned earlier, the PIXOUT1 and PIXOUT2 signals may be converted into corresponding digital values P1 and P2 by an appropriate ADC unit (not shown). In certain embodiments, these P1 and P2 values may be used in equation (2) or equation (3) above to determine a pixel-specific distance/range between the pixel 43 and the 3D object 26. The SD-based charge transfer illustrated in FIG. 10 allows for a generation of a pair of pixel-specific CDS outputs, as discussed earlier with reference to discussion of FIG. 9. The CDS-based signal processing provides for additional noise reduction, as also mentioned before.

In summary, the pixel designs as per teachings of the present disclosure use one or more high-gain PDs in combination with a PPD (or similar analog charge storage device), which performs as a time-to-charge converter whose AM-based charge transfer operation is controlled by outputs from the one or more high-gain PDs in the pixel to determine TOF. In the present disclosure, the PPD charge transfer is stopped to record TOF only when an output from a high-gain PD is triggered within a very short, pre-defined time interval—such as, for example, when an electronic shutter is “on.” As a result, an all-weather autonomous navigation system as per teachings of the present disclosure may provide improved vision for drivers under difficult driving conditions such as, for example, low light, fog, bad weather, and so on.

FIG. 11 depicts an exemplary flowchart 195 showing how a TOF value may be determined in the system 15 of FIGS. 1-2 according to one embodiment of the present disclosure. Various steps illustrated in FIG. 11 may be performed by a single module or a combination of modules or system components in the system 15. In the discussion herein, by way of an example only, specific tasks are described as being performed by specific modules or system components. Other modules or system components may be suitably configured to perform such tasks as well. As noted at block 197, initially, the system 15 (more specifically, the projector module 22) may project a laser pulse, such as the pulse 28 in FIG. 2, onto a 3D object, like the object 26 in FIG. 2. At block 198, the processor 19 (or the image processing unit 46 in certain embodiments) may apply an analog modulating signal, such as the VTX signal 99 in FIG. 6, to a device in a pixel, such as the PPD 89 in the pixel 50 or 67 (as per design choice). As mentioned earlier, the pixel 50 or 67 may be any of the pixels 43 in the pixel array 42 in FIG. 2. Furthermore, as noted at block 198, the device—such as the PPD 89—may be operable to store an analog charge. At block 199, the image processing unit 46 may initiate transfer of a portion of the analog charge from the device (like the PPD 89) based on modulation received from the analog modulating signal, such as the VTX signal 99. To initiate such charge transfer, the image processing unit 46 may provide various external signals—such as the shutter signal 61, the VPIX signal 104, and the RST signal 98—to the relevant pixel 50 or 67 at the logic levels illustrated in the exemplary timing diagram of FIG. 6.

At block 200, a returned pulse, such as the returned pulse 37, may be detected using the pixel 50 (or 67). As mentioned earlier, the returned pulse 37 is the projected laser pulse 28 reflected from the 3D object 26. As noted at block 200, the pixel 50 (or 67) may include a PD unit—such as the PD unit 52 (or the PD unit 68)—having at least one PD, like the PD 55 (or the PD 70), that converts luminance received in the returned pulse 37 into an electrical signal and that has a conversion gain that satisfies a threshold. In particular embodiments, the threshold is at least 400 μV per photon, as mentioned before. As noted at block 201, this electrical signal may be processed using an amplifier unit—such as the sense amplifier 60 (or the gainstage in the output unit 69)—in the pixel 50 (or 67) to responsively generate an intermediate output. In the embodiment of FIG. 3, such intermediate output is represented by the line 62, whereas it is represented by the line 78 in the embodiment of FIG. 4. As noted with reference to discussion of FIGS. 5 and 9, the relevant logic unit 86 (FIG. 5) or 144 (FIG. 9) (as per design choice) may process the intermediate output 87 (which may be the output at line 62 or 78, as applicable) and may place the TXEN signal 96 (FIG. 5) or 152 (FIG. 9) in the logic 0 (low) state. The logic 0 level of the TXEN signal 96 or 152 turns off the first transistor 90 and the second transistor 91 in the TCC unit 84 in FIG. 5 (or the corresponding transistors 146-147 in the TCC unit 140 in FIG. 9), which stops the transfer of charge to corresponding FD node 102 (or 162) from the PPD 89 (or 142). Thus, at block 202, the circuit in the relevant TCC unit 84 (or 140) may terminate the earlier-initiated transfer of the portion of the analog charge (at block 199) in response to generation of the intermediate output 87 within a pre-defined time interval—such as, for example, within the shutter “on” period 125 in FIG. 8 (or the corresponding period 189 in FIG. 10).

As discussed earlier with reference to FIGS. 5 and 9, the portion of the charge transferred to the respective FD node 102 (FIG. 5) or 162 (FIG. 9) (until the transfer is terminated at block 202) may be read out as a Pixout1 signal and converted into an appropriate digital value “P1”. The digital value “P1” may be used—along with a subsequently-generated digital value “P2” (for Pixout2 signal)—to obtain the TOF information from the ratio P1/(P1+P2), as outlined before. Thus, as noted at block 203, either the image processing unit 46 or the processor 19 in the system 15 may determine the TOF value of the returned pulse 37 based on the portion of the analog charge transferred upon termination (at block 202).

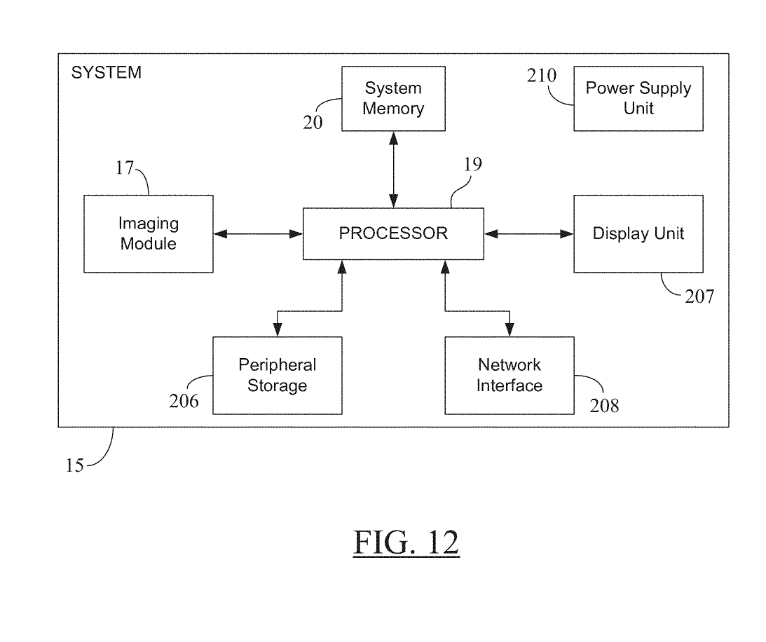

FIG. 12 depicts an overall layout of the system 15 in FIGS. 1-2 according to one embodiment of the present disclosure. Hence, for ease of reference and discussion, the same reference numerals are used in FIGS. 1-2 and 12 for the common system components/units.

As discussed earlier, the imaging module 17 may include the desired hardware shown in the exemplary embodiments of FIGS. 3-5, 7, and 9, as applicable, to accomplish 2D/3D imaging and TOF measurements as per the inventive aspects of the present disclosure. The processor 19 may be configured to interface with a number of external devices. In one embodiment, the imaging module 17 may function as an input device that provides data inputs—in the form of processed pixel outputs such as, for example, the P1 and P2 values—to the processor 19 for further processing. The processor 19 may also receive inputs from other input devices (not shown) that may be part of the system 15. Some examples of such input devices include a computer keyboard, a touchpad, a touch-screen, a joystick, a physical or virtual “clickable button,” and/or a computer mouse/pointing device. In FIG. 12, the processor 19 is shown coupled to the system memory 20, a peripheral storage unit 206, one or more output devices 207, and a network interface unit 208. In FIG. 12, a display unit is shown as an output device 207. In some embodiments, the system 15 may include more than one instance of the devices shown. Some examples of the system 15 include a computer system (desktop or laptop), a tablet computer, a mobile device, a cellular phone, a video gaming unit or console, a machine-to-machine (M2M) communication unit, a robot, an automobile, a virtual reality equipment, a stateless “thin” client system, a car's dash-cam or rearview camera system, an autonomous navigation system, or any other type of computing or data processing device. In various embodiments, all of the components shown in FIG. 12 may be housed within a single housing. Thus, the system 15 may be configured as a standalone system or in any other suitable form factor. In some embodiments, the system 15 may be configured as a client system rather than a server system. In particular embodiments, the system 15 may include more than one processor (e.g., in a distributed processing configuration). When the system 15 is a multiprocessor system, there may be more than one instance of the processor 19 or there may be multiple processors coupled to the processor 19 via their respective interfaces (not shown). The processor 19 may be a System on Chip (SoC) and/or may include more than one Central Processing Unit (CPU).

As mentioned earlier, the system memory 20 may be any semiconductor-based storage system such as, for example, DRAM, SRAM, PRAM, RRAM, CBRAM, MRAM, STT-MRAM, and the like. In some embodiments, the memory unit 20 may include at least one 3DS memory module in conjunction with one or more non-3DS memory modules. The non-3DS memory may include Double Data Rate or Double Data Rate 2, 3, or 4 Synchronous Dynamic Random Access Memory (DDR/DDR2/DDR3/DDR4 SDRAM), or Rambus® DRAM, flash memory, various types of Read Only Memory (ROM), etc. Also, in some embodiments, the system memory 20 may include multiple different types of semiconductor memories, as opposed to a single type of memory. In other embodiments, the system memory 20 may be a non-transitory data storage medium.

The peripheral storage unit 206, in various embodiments, may include support for magnetic, optical, magneto-optical, or solid-state storage media such as hard drives, optical disks (such as Compact Disks (CDs) or Digital Versatile Disks (DVDs)), non-volatile Random Access Memory (RAM) devices, flash memories, and the like. In some embodiments, the peripheral storage unit 206 may include more complex storage devices/systems such as disk arrays (which may be in a suitable RAID (Redundant Array of Independent Disks) configuration) or Storage Area Networks (SANs), and the peripheral storage unit 206 may be coupled to the processor 19 via a standard peripheral interface such as a Small Computer System Interface (SCSI) interface, a Fibre Channel interface, a Firewire® (IEEE 1394) interface, a Peripheral Component Interface Express (PCI Express™) standard based interface, a Universal Serial Bus (USB) protocol based interface, or another suitable interface. Various such storage devices may be non-transitory data storage media.

The display unit 207 may be an example of an output device. Other examples of an output device include a graphics/display device, a computer screen, an alarm system, a CAD/CAM (Computer Aided Design/Computer Aided Machining) system, a video game station, a smartphone display screen, a dashboard-mounted display screen in an automobile, or any other type of data output device. In some embodiments, the input device(s), such as the imaging module 17, and the output device(s), such as the display unit 207, may be coupled to the processor 19 via an I/O or peripheral interface(s).

In one embodiment, the network interface 208 may communicate with the processor 19 to enable the system 15 to couple to a network (not shown). In another embodiment, the network interface 208 may be absent altogether. The network interface 208 may include any suitable devices, media and/or protocol content for connecting the system 15 to a network—whether wired or wireless. In various embodiments, the network may include Local Area Networks (LANs), Wide Area Networks (WANs), wired or wireless Ethernet, the Internet, telecommunication networks, satellite links, or other suitable types of network.

The system 15 may include an on-board power supply unit 210 to provide electrical power to various system components illustrated in FIG. 12. The power supply unit 210 may receive batteries or may be connectable to an AC electrical power outlet or an automobile-based power outlet. In one embodiment, the power supply unit 210 may convert solar energy or other renewable energy into electrical power.

In one embodiment, the imaging module 17 may be integrated with a high-speed interface such as, for example, a Universal Serial Bus 2.0 or 3.0 (USB 2.0 or 3.0) interface or above, that plugs into any Personal Computer (PC) or laptop. A non-transitory, computer-readable data storage medium, such as, for example, the system memory 20 or a peripheral data storage unit such as a CD/DVD may store program code or software. The processor 19 and/or the image processing unit 46 (FIG. 2) in the imaging module 17 may be configured to execute the program code, whereby the device 15 may be operative to perform the 2D imaging (for example, grayscale image of a 3D object), TOF and range measurements, and generation of a 3D image of an object using the pixel-specific distance/range values, as discussed hereinbefore—such as, for example, the operations discussed earlier with reference to FIGS. 1-11. For example, in certain embodiments, upon execution of the program code, the processor 19 and/or the image processing unit 46 may suitably configure (or activate) relevant circuit components to apply appropriate input signals, like the Shutter, RST, VTX, SEL signals, and so on, to the pixels 43 in the pixel array 42 to enable capture of the light from a returned laser pulse and to subsequently process the pixel outputs for pixel-specific P1 and P2 values needed for TOF and range measurements. The program code or software may be proprietary software or open source software which, upon execution by the appropriate processing entity—such as the processor 19 and/or the image processing unit 46—may enable the processing entity to process various pixel-specific ADC outputs (P1 and P2 values), determine range values, render the results in a variety of formats including, for example, displaying a 3D image of the distant object based on TOF-based range measurements. In certain embodiments, the image processing unit 46 in the imaging module 17 may perform some of the processing of pixel outputs before the pixel output data are sent to the processor 19 for further processing and display. In other embodiments, the processor 19 also may perform some or all of the functionality of the image processing unit 46, in which case, the image processing unit 46 may not be a part of the imaging module 17.

In the preceding description, for purposes of explanation and not limitation, specific details are set forth (such as particular architectures, waveforms, interfaces, techniques, etc.) in order to provide a thorough understanding of the disclosed technology. However, it will be apparent to those skilled in the art that the disclosed technology may be practiced in other embodiments that depart from these specific details. That is, those skilled in the art will be able to devise various arrangements which, although not explicitly described or shown herein, embody the principles of the disclosed technology. In some instances, detailed descriptions of well-known devices, circuits, and methods are omitted so as not to obscure the description of the disclosed technology with unnecessary detail. All statements herein reciting principles, aspects, and embodiments of the disclosed technology, as well as specific examples thereof, are intended to encompass both structural and functional equivalents thereof. Additionally, it is intended that such equivalents include both currently known equivalents as well as equivalents developed in the future, such as, for example, any elements developed that perform the same function, regardless of structure.

Thus, for example, it will be appreciated by those skilled in the art that block diagrams herein (e.g., in FIGS. 1-2 and 12) can represent conceptual views of illustrative circuitry or other functional units embodying the principles of the technology. Similarly, it will be appreciated that the flowchart in FIG. 11 represents various processes which may be substantially performed by a processor (e.g., the processor 19 and/or the image processing unit 46 in FIG. 2) in conjunction with various system components such as, for example, the projector module 22, the 2D pixel array 42, and the like. Such a processor may include, by way of example, a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), and/or a state machine. Some or all of the processing functionalities described above in the context of FIGS. 1-12 also may be provided by such a processor, in the hardware and/or software.

When certain inventive aspects require software-based processing, such software or program code may reside in a computer-readable data storage medium. As noted earlier, such data storage medium may be part of the peripheral storage 206, or may be part of the system memory 20 or any internal memory (not shown) of the image sensor unit 24, or the processor's 19 internal memory (not shown). In one embodiment, the processor 19 and/or the image processing unit 46 may execute instructions stored on such a medium to carry out the software-based processing. The computer-readable data storage medium may be a non-transitory data storage medium containing a computer program, software, firmware, or microcode for execution by a general purpose computer or a processor mentioned above. Examples of computer-readable storage media include a ROM, a RAM, a digital register, a cache memory, semiconductor memory devices, magnetic media such as internal hard disks, magnetic tapes and removable disks, magneto-optical media, and optical media such as CD-ROM disks and DVDs.

Alternative embodiments of the imaging module 17 or the system 15 comprising such an imaging module according to inventive aspects of the present disclosure may include additional components responsible for providing additional functionality, including any of the functionality identified above and/or any functionality necessary to support the solution as per the teachings of the present disclosure. Although features and elements are described above in particular combinations, each feature or element can be used alone without the other features and elements or in various combinations with or without other features. As mentioned before, various 2D and 3D imaging functions discussed herein may be provided through the use of hardware (such as circuit hardware) and/or hardware capable of executing software/firmware in the form of coded instructions or microcode stored on a computer-readable data storage medium (mentioned above). Thus, such functions and illustrated functional blocks are to be understood as being either hardware-implemented and/or computer-implemented, and thus machine-implemented.

The foregoing describes a system and method in which a DTOF technique is combined with analog amplitude modulation (AM) within each pixel in a pixel array. No SPADs or APDs are used in the pixels. Instead, each pixel has a PD with a conversion gain of over 400 μV/e− and PDE of more than 45%, operating in conjunction with a PPD (or a similar analog storage device). The TOF information is added to the received light signal by the analog domain-based single-ended to differential converter inside the pixel itself. The output of the PD in a pixel is used to control the operation of the PPD. The charge transfer from the PPD is stopped—and, hence, TOF value and range of an object are recorded—when the output from the PD in the pixel is triggered within a pre-defined time interval. Such pixels provide for an improved autonomous navigation system—with an AM-based DTOF sensor—for drivers under difficult driving conditions such as, for example, low light, fog, bad weather, and so on.

As will be recognized by those skilled in the art, the innovative concepts described in the present application can be modified and varied over a wide range of applications. Accordingly, the scope of patented subject matter should not be limited to any of the specific exemplary teachings discussed above, but is instead defined by the following claims.

What is claimed is:

1. A pixel in an image sensor, said pixel comprising:
a Photo Diode (PD) unit having at least one PD that converts received luminance into an electrical signal, wherein the at least one PD has a conversion gain that satisfies a threshold;
an amplifier unit connected in series with the PD unit to amplify the electrical signal and to responsively generate an intermediate output; and
a Time-to-Charge Converter (TCC) unit coupled to the amplifier unit and receiving the intermediate output therefrom, wherein the TCC unit includes:
a device that stores an analog charge, and
a control circuit coupled to the device, wherein the control circuit performs operations comprising:
initiating transfer of a first portion of the analog charge from the device,
terminating the transfer in response to receipt of the intermediate output within a pre-defined time interval, and
generating a first pixel-specific output for the pixel based on the first portion of the analog charge transferred.

2. The pixel of claim 1, wherein each of the PD unit, the amplifier unit, and the TCC unit comprises a Complementary Metal Oxide Semiconductor (CMOS) portion.

3. The pixel of claim 1, wherein the PD unit includes:
a first PD that receives the luminance and generates the electrical signal in response thereto, wherein the first PD has the conversion gain that satisfies the threshold; and
a second PD connected in parallel to the first PD, wherein the second PD is unexposed to the luminance and generates a reference signal based on a level of darkness detected thereby.

4. The pixel of claim 3, wherein the amplifier unit includes:
a sense amplifier connected in series with the first and the second PDs to amplify the electrical signal upon sensing the electrical signal vis-à-vis the reference signal, wherein the sense amplifier generates the intermediate output upon amplifying the electrical signal in response to a control signal received thereby.

5. The pixel of claim 4, wherein the sense amplifier is a current sense amplifier.

6. The pixel of claim 1, wherein the device is one of the following:
a Pinned Photo Diode (PPD);
a photogate; and
a capacitor.

7. The pixel of claim 1, wherein the control circuit includes an output terminal, and wherein the control circuit further performs the operations comprising:
receiving an analog modulating signal;
further receiving an external input;
transferring the first portion of the analog charge as the first pixel-specific output through the output terminal in response to the external input and based on modulation provided by the analog modulating signal; and
transferring a second portion of the analog charge as a second pixel-specific output through the output terminal in response to the external input, wherein the second portion is substantially equal to a remainder of the analog charge after the first portion is transferred.

8. The pixel of claim 7, wherein the control circuit includes a first node and a second node, and wherein the control circuit further performs the operations comprising:
transferring the first portion of the analog charge from the device to the first node, from the first node to the second node, and from the second node to the output terminal as the first pixel-specific output; and
transferring the second portion of the analog charge from the device to the first node, from the first node to the second node, and from the second node to the output terminal as the second pixel-specific output.

9. The pixel of claim 1, wherein the threshold is at least 400 μV per photoelectron.

10. A method comprising:
projecting a laser pulse onto a three-dimensional (3D) object;
applying an analog modulating signal to a device in a pixel, wherein the device stores an analog charge;
initiating transfer of a first portion of the analog charge from the device based on modulation received from the analog modulating signal;
detecting a returned pulse using the pixel, wherein the returned pulse is the projected laser pulse reflected from the 3D object, and wherein the pixel includes a Photo Diode (PD) unit having at least one PD that converts luminance received in the returned pulse into an electrical signal and that has a conversion gain that satisfies a threshold;
processing the electrical signal using an amplifier unit in the pixel to responsively generate an intermediate output;
terminating the transfer of the first portion of the analog charge in response to generation of the intermediate output within a pre-defined time interval; and
determining a Time of Flight (TOF) value of the returned pulse based on the first portion of the analog charge transferred upon termination.

11. The method of claim 10, further comprising:
generating a first pixel-specific output of the pixel from the first portion of the analog charge transferred from the device;
transferring a second portion of the analog charge from the device, wherein the second portion is substantially equal to a remainder of the analog charge after the first portion is transferred;
generating a second pixel-specific output of the pixel from the second portion of the analog charge transferred from the device;
sampling the first and the second pixel-specific outputs using an Analog-to-Digital Converter (ADC) unit; and
based on the sampling, generating a first signal value corresponding to the first pixel-specific output and a second signal value corresponding to the second pixel-specific output using the ADC unit.

12. The method of claim 11, further comprising:
determining the TOF value of the returned pulse using a ratio of the first signal value to a total of the first and the second signal values.

13. The method of claim 12, further comprising:
determining a distance to the 3D object based on the TOF value.

14. The method of claim 10, further comprising:
further applying a shutter signal to the amplifier unit, wherein the shutter signal is applied a pre-determined time period after projecting the laser pulse;
detecting the returned pulse using the pixel while the shutter signal as well as the analog modulating signal are active;
providing a termination signal upon generation of the intermediate output while the shutter signal is active; and
terminating the transfer of the first portion of the analog charge in response to the termination signal.

15. The method of claim 10, wherein detecting the returned pulse includes:
receiving the luminance at a first PD in the PD unit, wherein the first PD has the conversion gain that satisfies the threshold;
generating the electrical signal using the first PD; and
further generating a reference signal using a second PD in the PD unit, wherein the second PD is connected in parallel to the first PD, is unexposed to the luminance, and generates the reference signal based on a level of darkness detected thereby.

16. The method of claim 15, wherein the amplifier unit is a sense amplifier connected in series with the first and the second PDs, and wherein processing the electrical signal includes:
providing a shutter signal to the sense amplifier;
sensing the electrical signal vis-à-vis the reference signal using the sense amplifier while the shutter signal is active; and
generating the intermediate output by amplifying the electrical signal using the sense amplifier while the shutter signal is active.

17. The method of claim 10, wherein projecting the laser pulse includes:
projecting the laser pulse using a light source that is one of the following:
a laser light source;
a light source that produces light in a visible spectrum;
a light source that produces light in a non-visible spectrum;
a monochromatic illumination source;
an Infrared (IR) laser;
an X-Y addressable light source;
a point source with two-dimensional (2D) scanning capability;
a sheet source with one-dimensional (1D) scanning capability; and
a diffused laser.

18. The method of claim 10, wherein the threshold is at least 400 μV per photon.

19. A system comprising:
a light source that projects a laser pulse onto a three-dimensional (3D) object;
a plurality of pixels, wherein each pixel includes:
a pixel-specific Photo Diode (PD) unit having at least one PD that converts luminance received in a returned pulse into an electrical signal, wherein the at least one PD has a conversion gain that satisfies a threshold, and wherein the returned pulse results from reflection of the projected laser pulse by the 3D object,
a pixel-specific amplifier unit connected in series with the pixel-specific PD unit to amplify the electrical signal and to responsively generate an intermediate output, and
a pixel-specific Time-to-Charge Converter (TCC) unit coupled to the pixel-specific amplifier unit and receiving the intermediate output therefrom, wherein the pixel-specific TCC unit includes:
a device that stores an analog charge, and
a control circuit coupled to the device, wherein the control circuit performs operations comprising:
initiating transfer of a pixel-specific first portion of the analog charge from the device,
terminating the transfer of the pixel-specific first portion upon receipt of the intermediate output within a pre-defined time interval,
generating a first pixel-specific output for the pixel based on the pixel-specific first portion of the analog charge transferred,
transferring a pixel-specific second portion of the analog charge from the device, wherein the pixel-specific second portion is substantially equal to a remainder of the analog charge after the pixel-specific first portion is transferred, and
generating a second pixel-specific output for the pixel based on the pixel-specific second portion of the analog charge transferred;
a memory for storing program instructions; and
a processor coupled to the memory and to the plurality of pixels, wherein the processor executes the program instructions, whereby the processor performs the following operations for each pixel in the plurality of pixels:
facilitating transfers of the pixel-specific first and second portions of the analog charge, respectively,
receiving the first and the second pixel-specific outputs,
generating a pixel-specific pair of signal values based on the first and the second pixel-specific outputs, respectively, wherein the pixel-specific pair of signal values includes a pixel-specific first signal value and a pixel-specific second signal value,
determining a corresponding pixel-specific Time of Flight (TOF) value of the returned pulse using the pixel-specific first signal value and the pixel-specific second signal value, and
determining a pixel-specific distance to the 3D object based on the pixel-specific TOF value.

20. The system of claim 19, wherein the processor provides an analog modulating signal to the control circuit in the pixel-specific TCC unit in each pixel, and wherein the control circuit in the pixel-specific TCC unit controls an amount of the pixel-specific first portion of the analog charge to be transferred based on modulation provided by the analog modulating signal.

21. The system of claim 19, wherein the processor triggers the light source to project the laser pulse, wherein the light source is one of the following:
a laser light source;
a light source that produces light in a visible spectrum;
a light source that produces light in a non-visible spectrum;
a monochromatic illumination source;
an Infrared (IR) laser;
an X-Y addressable light source;
a point source with two-dimensional (2D) scanning capability;
a sheet source with one-dimensional (1D) scanning capability; and
a diffused laser.

22. The system of claim 19, wherein the device in the pixel-specific TCC unit is one of the following:
a Pinned Photo Diode (PPD);
a photogate; and
a capacitor.

23. The system of claim 19, wherein the threshold is at least 400 μV per photoelectron.
